(19) United States
(12) Patent Application Publication
(10) Pub. No.: US 2026/0190471 A1
(43) Pub. Date: Jul. 2, 2026

(54) SEMICONDUCTOR DEVICE

(71) Applicant: SAMSUNG ELECTRONICS CO., LTD., Suwon-si (KR)

(72) Inventors: Song Jae LEE, Suwon-si (KR); Soo Hun HONG, Suwon-si (KR); Se Yeon PARK, Suwon-si (KR); Han Seul SHIN, Suwon-si (KR); Hyun Ki YOON, Suwon-si (KR)

(73) Assignee: SAMSUNG ELECTRONICS CO., LTD., Suwon-si (KR)

(21) Appl. No.: 19/271,206

(22) Filed: Jul. 16, 2025

(30) Foreign Application Priority Data
Dec. 26, 2024 (KR) 10-2024-0196718

(51) Int. Cl. H10D 84/85; H10D 84/01

(52) U.S. Cl. CPC H10D 84/851; H10D 84/0167; H10D 84/017; H10D 84/0186

(57) ABSTRACT

A semiconductor device includes: a substrate, an active pattern including a first portion and a second portion that extend in a first horizontal direction on an upper surface of the substrate and are spaced apart from each other in a second horizontal direction; a first plurality of nanosheets stacked on the first portion; and a second plurality of nanosheets stacked on the second portion. The semiconductor device further includes a ground structure including a third plurality of nanosheets stacked on the first and second portions; and a semiconductor layer between the third plurality of nanosheets and including silicon germanium (SiGe); a first gate electrode surrounding the first and second plurality of nanosheets; a ground gate electrode covering an upper surface and sidewalls of the ground structure in the second horizontal direction; and a ground silicide layer between the ground structure and the ground gate electrode including a metal silicide.

### CROSS-REFERENCE TO RELATED APPLICATION

This application claims priority under 35 U.S.C. § 119 from Korean Patent Application No. 10-2024-0196718 filed on Dec. 26, 2024 in the Korean Intellectual Property Office, the disclosure of which is incorporated by reference herein in its entirety.

### BACKGROUND

### 1. Technical Field

The present disclosure relates to a semiconductor device and, more particularly to a semiconductor device including a MBCFETTM (Multi-Bridge Channel Field Effect Transistor).

### 2. Description of Related Art

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Because these multi-gate transistors utilize a three-dimensional channel, scaling becomes more feasible. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

One or more example embodiments provide a semiconductor device that may improve the integration density and may reduce the resistance of the route that grounds the substrate to the ground.

The aspects of the present disclosure are not limited to those mentioned above, and another aspect which is not mentioned may be clearly understood by those skilled in the art from the description below.

According to an aspect of the disclosure, a semiconductor device includes: a substrate; an active pattern including a first portion and a second portion, each of the first portion and the second portion extending in a first horizontal direction on an upper surface of the substrate, and the second portion being spaced apart from the first portion in a second horizontal direction different from the first horizontal direction; a first plurality of nanosheets stacked on the first portion of the active pattern, the first plurality of nanosheets being spaced apart from each other in a vertical direction; a second plurality of nanosheets stacked on the second portion of the active pattern, the second plurality of nanosheets being spaced apart from each other in the vertical direction and spaced apart from the first plurality of nanosheets in the second horizontal direction; a ground structure including: a third plurality of nanosheets stacked on the first portion and the second portion of the active pattern, the third plurality of nanosheets being spaced apart from each other in the vertical direction and spaced apart from each of the first plurality of nanosheets and the second plurality of nanosheets in the first horizontal direction; and a semiconductor layer between adjacent ones of the third plurality of nanosheets, wherein the semiconductor layer includes silicon germanium (SiGe); a first gate electrode extending in the second horizontal direction on each of the first portion and the second portion of the active pattern, the first gate electrode surrounding each of the first plurality of nanosheets and each of the second plurality of nanosheets; a ground gate electrode extending in the second horizontal direction on each of the first portion and the second portion of the active pattern, the ground gate electrode being spaced apart from the first gate electrode in the first horizontal direction and covering an upper surface and sidewalls of the ground structure; and a ground silicide layer between and in contact with the ground structure and the ground gate electrode, the ground silicide layer including a metal silicide.

According to an aspect of the disclosure, a semiconductor device includes: a substrate including a P-channel Metal-Oxide-Semiconductor (PMOS) region and an N-channel Metal-Oxide-Semiconductor (NMOS) region; a first active pattern extending in a first horizontal direction on an upper surface of the substrate in the PMOS region; a second active pattern extending in the first horizontal direction on the upper surface of the substrate in the NMOS region, the second active pattern being spaced apart from the first active pattern in a second horizontal direction different from the first horizontal direction; a field insulating layer on the upper surface of the substrate and surrounding sidewalls the first active pattern and sidewalls of the second active pattern; a first plurality of nanosheets stacked on the first active pattern and spaced apart from each other in a vertical direction; a first ground structure including: a second plurality of nanosheets stacked on the first active pattern, the second plurality of nanosheets being spaced apart from each other in the vertical direction and spaced apart from the first plurality of nanosheets in the first horizontal direction; and a first semiconductor layer between adjacent ones of the second plurality of nanosheets, the first semiconductor layer including silicon germanium (SiGe); a third plurality of nanosheets stacked on the second active pattern, the third plurality of nanosheets being spaced apart from each other in the vertical direction and spaced apart from the first plurality of nanosheets in the second horizontal direction; a second ground structure including: a fourth plurality of nanosheets stacked on the second active pattern, the fourth plurality of nanosheets being spaced apart from each other in the vertical direction and spaced apart from the third plurality of nanosheets in the first horizontal direction; and a second semiconductor layer between adjacent ones of the fourth plurality of nanosheets, the second semiconductor layer being spaced apart from the first ground structure in the second horizontal direction, the second semiconductor layer including silicon germanium (SiGe); a gate electrode extending in the second horizontal direction on each of the first active pattern and the second active pattern and surrounding each of the first plurality of nanosheets and the third plurality of nanosheets; and a ground gate electrode extending in the second horizontal direction on each of the first active pattern and the second active pattern, the ground gate electrode being spaced apart from the gate electrode in the first horizontal direction, the ground gate electrode covering an upper surface and sidewalls of the first ground structure and upper surface and sidewalls of the second ground structure, the ground gate electrode being in contact with an upper surface of the field insulating layer.

According to an aspect of the disclosure, a semiconductor device includes: a substrate including a P-channel Metal-Oxide-Semiconductor (PMOS) region and an N-channel Metal-Oxide-Semiconductor (NMOS) region; a first active pattern extending in a first horizontal direction on an upper surface of the substrate in the PMOS region, the first active pattern including: a first portion; a second portion spaced apart from the first portion in a second horizontal direction different from the first horizontal direction; and a third portion connecting the first portion and the second portion; a second active pattern extending in the first horizontal direction on the upper surface of the substrate in the NMOS region, the second active pattern being spaced apart from the first active pattern in the second horizontal direction; a first ground structure including: a first plurality of nanosheets stacked on each of the first portion, the second portion and the third portion of the first active pattern, the first plurality of nanosheets being spaced apart from each other in a vertical direction; and a first semiconductor layer between adjacent ones of the first plurality of nanosheets, wherein the first semiconductor layer including silicon germanium (SiGe); a second ground structure spaced apart from the first ground structure in the second horizontal direction, the second ground structure including: a second plurality of nanosheets stacked on the second active pattern, the second plurality of nanosheets being spaced apart from each other in the vertical direction; and a second semiconductor layer between adjacent ones of the second plurality of nanosheets, the second semiconductor layer including silicon germanium (SiGe); a first gate electrode extending in the second horizontal direction on each of the first portion and the second portion of the first active pattern and on the second active pattern; a ground gate electrode extending in the second horizontal direction on each of the first portion, the second portion and the third portion of the first active pattern and on the second active pattern, the ground gate electrode being spaced apart from the first gate electrode in the first horizontal direction, the ground gate electrode covering an upper surface and sidewalls of the first ground structure and an upper surface and sidewalls of the second ground structure; a second gate electrode extending in the second horizontal direction on each of the first portion and the second portion of the first active pattern and on the second active pattern, the second gate electrode being spaced apart from the ground gate electrode in the first horizontal direction; a first gate cut between the first portion of the first active pattern and the second portion of the first active pattern, the first gate cut separating the first gate electrode in the second horizontal direction; a second gate cut between the first ground structure and the second ground structure, the second gate cut separating the ground gate electrode in the second horizontal direction; and a third gate cut between the first portion of the first active pattern and the second portion of the first active pattern, the third gate cut separating the second gate electrode in the second horizontal direction, wherein the third portion of the first active pattern is between the first gate cut and the third gate cut.

According to an aspect of the disclosure, a method of manufacturing a semiconductor device includes: providing a substrate; providing, on the substrate, an active pattern including a first portion and a second portion, wherein each of the first portion and the second portion extend in a first horizontal direction on an upper surface of the substrate, and wherein the second portion is spaced apart from the first portion in a second horizontal direction different from the first horizontal direction; stacking a first plurality of nanosheets on the first portion of the active pattern, wherein the first plurality of nanosheets are spaced apart from each other in a vertical direction; stacking a second plurality of nanosheets on the second portion of the active pattern, wherein the second plurality of nanosheets are spaced apart from each other in the vertical direction, and wherein the second plurality of nanosheets are spaced apart from the first plurality of nanosheets in the second horizontal direction; providing a ground structure including: an upper surface; a plurality of sidewalls; and a third plurality of nanosheets stacked on the first portion and the second portion of the active pattern, wherein the third plurality of nanosheets are spaced apart from each other in the vertical direction, wherein the providing the ground structure includes providing a semiconductor layer disposed between adjacent ones of the third plurality of nanosheets, wherein the third plurality of nanosheets are spaced apart from each of the first plurality of nanosheets and the second plurality of nanosheets in the first horizontal direction, and wherein the semiconductor layer includes silicon germanium (SiGe); providing a first gate electrode extending in the second horizontal direction on each of the first portion and the second portion of the active pattern, wherein the first gate electrode surrounds each one of the first plurality of nanosheets and each one of the second plurality of nanosheets; providing a ground gate electrode extending in the second horizontal direction on each of the first portion and the second portion of the active pattern, wherein the ground gate electrode is spaced apart from the first gate electrode in the first horizontal direction, wherein the ground gate electrode covers the upper surface and each of the plurality of sidewalls of the ground structure; and providing a ground silicide layer between the ground structure and the ground gate electrode, wherein the ground silicide layer contacts each of the ground structure and the ground gate electrode, and wherein the ground silicide layer includes a metal silicide.

The method of manufacturing the semiconductor device may include: providing the ground structure wherein the semiconductor layer includes a first sidewall extending in the second horizontal direction, wherein the third plurality of nanosheets include a second sidewall extending in the second horizontal direction, and wherein the first sidewall has a continuous slope profile with the second sidewall.

The method of manufacturing the semiconductor device may include: providing a field insulating layer on the upper surface of the substrate, wherein the field insulating layer surrounds a sidewall of the active pattern, and wherein the field insulating layer contacts a bottom surface of the ground gate electrode.

The method of manufacturing the semiconductor device may include: providing each of the third plurality of nanosheets and the semiconductor layer including doped impurities.

The method of manufacturing the semiconductor device may include: providing the upper surface of the ground structure to be coplanar with an upper surface of an uppermost nanosheet of the first plurality of nanosheets.

The method of manufacturing the semiconductor device may include: providing a gate cut between the first portion of the active pattern and the second portion of the active pattern, wherein the gate cut separates the first gate electrode and extends in the second horizontal direction.

The method of manufacturing the semiconductor device may include: stacking a fourth plurality of nanosheets on the first portion of the active pattern, wherein the fourth plurality of nanosheets are spaced apart from each other in the vertical direction, and wherein the fourth plurality of nanosheets are spaced apart from the third plurality of nanosheets in the first horizontal direction; stacking a fifth plurality of nanosheets on the second portion of the active pattern, wherein the fifth plurality of nanosheets are spaced apart from each other in the vertical direction, wherein the fifth plurality of nanosheets are spaced apart from the third plurality of nanosheets in the first horizontal direction, and wherein the fifth plurality of nanosheets are spaced apart from the fourth plurality of nanosheets in the second horizontal direction; and providing a second gate electrode extending in the second horizontal direction on each of the first portion and the second portion of the active pattern, wherein the second gate electrode is spaced apart from the ground gate electrode in the first horizontal direction, and wherein the second gate electrode surrounds each of the fourth plurality of nanosheets and the fifth plurality of nanosheets.

The method of manufacturing the semiconductor device may include: providing a gate spacer on an upper surface of an uppermost nanosheet of the third plurality of nanosheets, wherein the ground gate electrode includes sidewalls, which are spaced apart in the first horizontal direction, and wherein the gate spacer contacts the sidewalls of the ground gate electrode.

The method of manufacturing the semiconductor device may include: providing the ground silicide layer wherein the ground silicide layer includes sidewalls, which are spaced apart in the first horizontal direction and which contact the gate spacer.

The method of manufacturing the semiconductor device may include: providing the active pattern, wherein the active pattern further includes a third portion connecting the first portion of the active pattern and the second portion of the active pattern, wherein the third portion of the active pattern overlaps with the ground gate electrode in the vertical direction, and wherein the third portion of the active pattern does not overlap with the first gate electrode in the vertical direction.

The method of manufacturing the semiconductor device may include: stacking the third plurality of nanosheets, wherein the third plurality of nanosheets overlaps with each of the first portion, the second portion and the third portion of the active pattern, in the vertical direction, and wherein a width of the third plurality of nanosheets in the second horizontal direction is greater than a width of the first plurality of nanosheets in the second horizontal direction.

The method of manufacturing the semiconductor device may include: providing a first capping pattern extending in the second horizontal direction on an upper surface of the first gate electrode; and providing a second capping pattern extending in the second horizontal direction on an upper surface of the ground gate electrode, wherein an upper surface of the first capping pattern and an upper surface of the second capping pattern are coplanar.

### BRIEF DESCRIPTION OF THE DRAWINGS

The above and other aspects and features will become more apparent from the following description of one or more example embodiments taken in conjunction with the accompanying drawings, in which:

FIG. 1 is a layout diagram for explaining a semiconductor device according to one or more example embodiments;

FIG. 2 is a cross-sectional view taken along the line A-A′ of FIG. 1, according to one or more example embodiments;

FIG. 3 is a cross-sectional view taken along the line B-B′ of FIG. 1, according to one or more example embodiments;

FIG. 4 is a cross-sectional view taken along the line C-C′ of FIG. 1, according to one or more example embodiments;

FIG. 5 is a cross-sectional view taken along the line D-D′ of FIG. 1, according to one or more example embodiments;

FIGS. 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40 and 41 are intermediate stage diagrams for explaining a method for fabricating a semiconductor device according to one or more example embodiments;

FIGS. 42 and 43 are cross-sectional views for explaining a semiconductor device according to one or more example embodiments;

FIG. 44 is a layout diagram for explaining a semiconductor device according to one or more example embodiments;

FIG. 45 is a cross-sectional view taken along the line E-E′ of FIG. 44, according to one or more example embodiments; and

FIG. 46 is a cross-sectional view taken along the line F-F′ of FIG. 44, according to one or more example embodiments.

### DETAILED DESCRIPTION

Hereinafter, one or more example embodiments will be described in detail with reference to the accompanying drawings. The same reference numerals are used for the same components in the drawings, and duplicate descriptions thereof are omitted.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

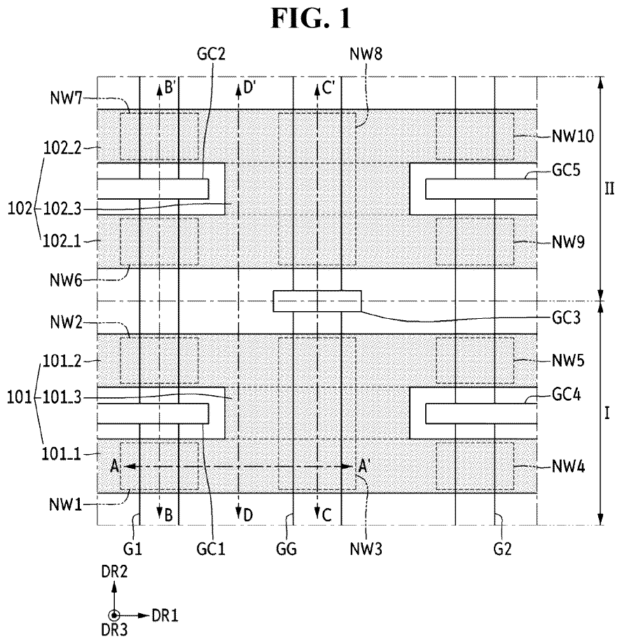

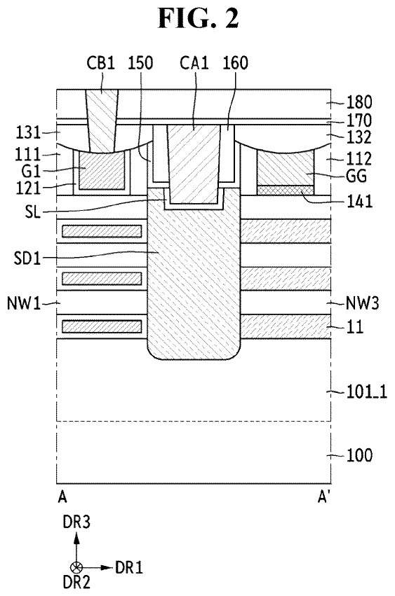

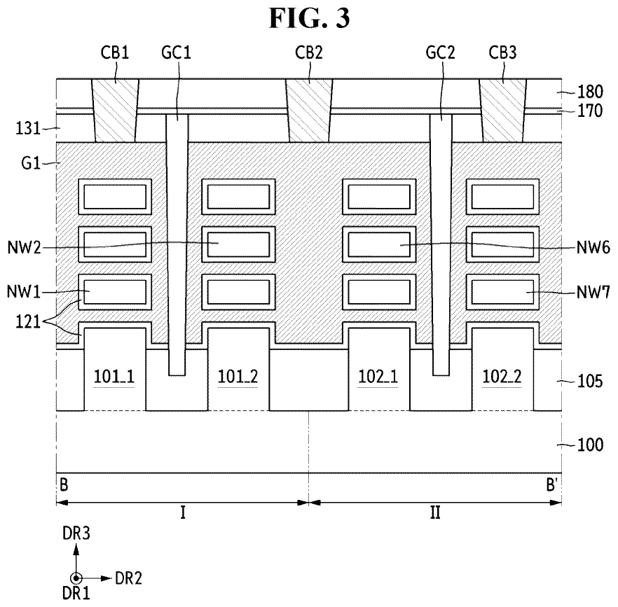

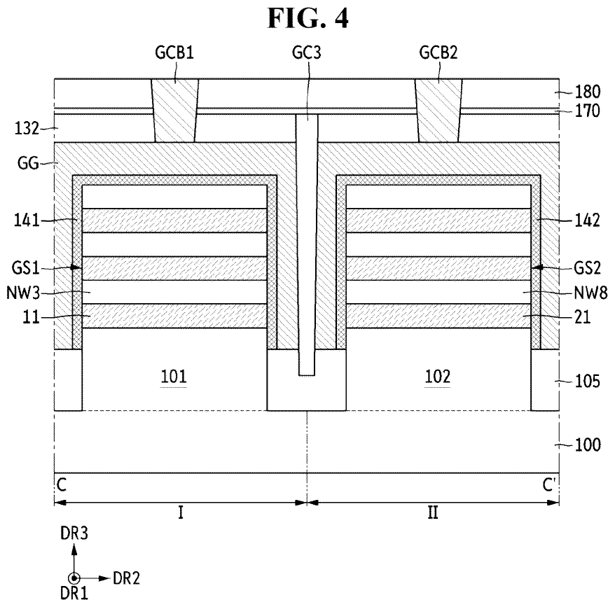

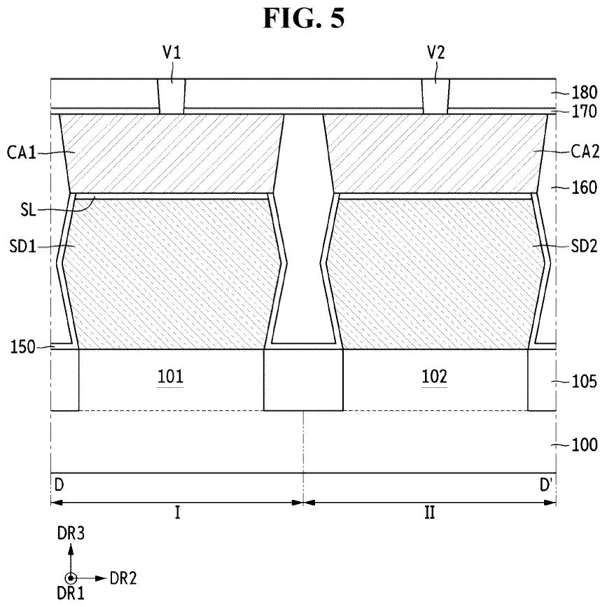

FIG. 1 is a schematic layout diagram for explaining a semiconductor device according to one or more example embodiments. FIG. 2 is a cross-sectional view taken along the line A-A′ of FIG. 1, according to one or more example embodiments. FIG. 3 is a cross-sectional view taken along the line B-B′ of FIG. 1, according to one or more example embodiments. FIG. 4 is a cross-sectional view taken along the line C-C′ of FIG. 1, according to one or more example embodiments. FIG. 5 is a cross-sectional view taken along the line D-D′ of FIG. 1, according to one or more example embodiments.

Referring to FIGS. 1, 2, 3, 4 and 5, the semiconductor device according to one or more example embodiments may include a substrate 100, first and second active patterns 101 and 102, a field insulating layer 105, a first, a second, a third, a fourth, a fifth, a sixth, a seventh, an eighth, a ninth and a tenth plurality of nanosheets NW1, NW2, NW3, NW4, NW5, NW6, NW7, NW8, NW9, and NW10, first and second gate electrodes G1 and G2, a ground gate electrode GG, first and second gate spacers 111 and 112, first and second ground structures GS1 and GS2, first and second semiconductor layers 11 and 21, a gate insulating layer 121, first and second capping patterns 131 and 132, first and second ground silicide layers 141 and 142, first and second source/drain regions SD1 and SD2, a first etching stop layer 150, a first interlayer insulating layer 160, first, second, third, fourth and fifth gate cuts GC1, GC2, GC3, GC4 and GC5, first and second source/drain contacts CA1 and CA2, a contact silicide layer SL, a second etching stop layer 170, a second interlayer insulating layer 180, first, second and third gate contacts CB1, CB2, and CB3, first and second ground gate contacts GCB1 and GCB2, and first and second vias V1 and V2.

The substrate 100 may be a silicon substrate or an SOI (silicon-on-insulator) substrate. Alternatively, the substrate 100 may include silicon germanium, SGOI (silicon germanium-on-insulator), indium antimonide, lead telluride compounds, indium arsenide, indium phosphide, gallium arsenide, or gallium antimonide, but one or more example embodiments are not limited thereto. For example, the substrate 100 may include a PMOS region I and an NMOS region II. The NMOS region II may be disposed adjacent to the PMOS region I in a second horizontal direction DR2. For example, the PMOS region I may be the region in which the PMOS transistor is formed, while the NMOS region II may be the region in which the NMOS transistor is formed. In other words, according to one or more example embodiments the NMOS transistor may be formed on the substrate 100 in the PMOS region I, and the PMOS transistor may be formed on the substrate 100 in the NMOS region II.

Hereinafter, the first horizontal direction DR1 and the second horizontal direction DR2 may be defined as directions parallel to the upper surface of the substrate 100. The second horizontal direction DR2 may be defined as a direction different from the first horizontal direction DR1. The vertical direction DR3 may be defined as a direction perpendicular to both the first horizontal direction DR1 and the second horizontal direction DR2. In other words, the vertical direction DR3 may be defined as a direction perpendicular to the upper surface of the substrate 100.

Each of the first and second active patterns 101 and 102 may be disposed on the upper surface of the substrate 100. Each of the first and second active patterns 101 and 102 may protrude from the upper surface of the substrate 100 in the vertical direction DR3. For example, each of the first and second active patterns 101 and 102 may be part of the substrate 100 or may include an epitaxial layer grown from the substrate 100. The first active pattern 101 may extend in the first horizontal direction DR1 on the upper surface of the substrate 100 in the PMOS region I. For example, the first active pattern 101 may include first, second and third portions 101_1, 101_2 and 101_3. Each of the first portion 101_1 and the second portion 101_2 of the first active pattern 101 may be extended in the first horizontal direction DR1 on the upper surface of the substrate 100 in the PMOS region I.

The third portion 101_3 of the first active pattern 101 may be disposed between the first portion 101_1 of the first active pattern 101 and the second portion 101_2 of the first active pattern 101. The third portion 101_3 of the first active pattern 101 may connect the first portion 101_1 of the first active pattern 101 and the second portion 101_2 of the first active pattern 101. For example, the third portion 101_3 of the first active pattern 101 may overlap with a portion of the first portion 101_1 of the first active pattern 101 and a portion of the second portion 101_2 of the first active pattern 101 in the second horizontal direction DR2. For example, the first active pattern 101 may not be positioned on either sidewall of the third portion 101_3 of the first active pattern 101 in the first horizontal direction DR1.

The second active pattern 102 may extend in the first horizontal direction DR1 on the upper surface of the substrate 100 in the NMOS region II. The second active pattern 102 may be spaced apart from the first active pattern 101 in the second horizontal direction DR2. For example, the second active pattern 102 may include first, second and third portions 102_1, 102_2 and 102_3. Each of the first portion 102_1 of the second active pattern 102 and the second portion 102_2 of the second active pattern 102 may be extended in the first horizontal direction DR1 on the upper surface of the substrate 100 in the NMOS region II. For example, the first portion 102_1 of the second active pattern 102 may be spaced apart from the second portion 101_2 of the first active pattern 101 in the second horizontal direction DR2.

The third portion 102_3 of the second active pattern 102 may be disposed between the first portion 102_1 of the second active pattern 102 and the second portion 102_2 of the second active pattern 102. The third portion 102_3 of the second active pattern 102 may connect the first portion 102_1 of the second active pattern 102 and the second portion 102_2 of the second active pattern 102. For example, the third portion 102_3 of the second active pattern 102 may overlap with a portion of the first portion 102_1 of the second active pattern 102 and a portion of the second portion 102_2 of the second active pattern 102 in the second horizontal direction DR2. For example, the second active pattern 102 may not be disposed on either sidewall of the third portion 102_3 of the second active pattern 102 in the first horizontal direction DR1.

The first, second, third, fourth and fifth plurality of nanosheets NW1, NW2, NW3, NW4 and NW5 may be disposed on the upper surface of the substrate 100 in the PMOS region I. The sixth, seventh, eighth, ninth and tenth plurality of nanosheets NW6, NW7, NW8, NW9 and NW10 may be disposed on the upper surface of the substrate 100 in the NMOS region II. Each of the first, second, third, fourth, fifth, sixth, seventh, eighth, ninth and tenth plurality of nanosheets NW1, NW2, NW3, NW4, NW5, NW6, NW7, NW8, NW9, and NW10 may include a plurality of nanosheets stacked and spaced apart from each other in the vertical direction DR3. In FIGS. 2, 3 and 4, each of the first, second, third, fourth, fifth, sixth, seventh, eighth, ninth and tenth plurality of nanosheets NW1, NW2, NW3, NW4, NW5, NW6, NW7, NW8, NW9, and NW10 is shown to include three nanosheets stacked and spaced apart from each other in the vertical direction DR3, but this is for the sake of convenience of description and is not intended to limit one or more example embodiments. In some example embodiments, each of the first, second, third, fourth, fifth, sixth, seventh, eighth, ninth and tenth plurality of nanosheets NW1, NW2, NW3, NW4, NW5, NW6, NW7, NW8, NW9, and NW10 may include four or more nanosheets stacked and spaced apart from each other in the vertical direction DR3. For example, each of the first, second, third, fourth, fifth, sixth, seventh, eighth, ninth and tenth plurality of nanosheets NW1, NW2, NW3, NW4, NW5, NW6, NW7, NW8, NW9, and NW10 may include silicon (Si). For example, the upper surface of the uppermost nanosheets of each of the first, second, third, fourth, fifth, sixth, seventh, eighth, ninth and tenth nanosheets NW1, NW2, NW3, NW4, NW5, NW6, NW7, NW8, NW9, and NW10 may be formed on the same plane.

The first, second, third, fourth and fifth plurality of nanosheets NW1, NW2, NW3, NW4 and NW5 may be disposed on the upper surface of the first active pattern 101. The first, second, third, fourth and fifth plurality of nanosheets NW1, NW2, NW3, NW4 and NW5 may be spaced apart from the upper surface of the first active pattern 101 in the vertical direction DR3. For example, the first plurality of nanosheets NW1 may be disposed on the upper surface of the first portion 101_1 of the first active pattern 101. The second plurality of nanosheets NW2 may be disposed on the upper surface of the second portion 101_2 of the first active pattern 101. The second plurality of nanosheets NW2 may be spaced apart from the first plurality of nanosheets NW1 in the second horizontal direction DR2. The third plurality of nanosheets NW3 may be disposed on the upper surfaces of the first, second and third portions 101_1, 101_2 and 101_3 of the first active pattern 101. In other words, the third plurality of nanosheets NW3 may overlap with each of the first, second and third portions 101_1, 101_2 and 101_3 of the first active pattern 101 in the vertical direction DR3. The third plurality of nanosheets NW3 may be spaced apart from the first and second pluralities of nanosheets NW1 and NW2 in the first horizontal direction DR1.

The fourth plurality of nanosheets NW4 may be disposed on the upper surface of the first portion 101_1 of the first active pattern 101. The fourth plurality of nanosheets NW4 may be spaced apart from the third plurality of nanosheets NW3 in the first horizontal direction DR1. A fifth plurality of nanosheets NW5 may be disposed on the upper surface of the second portion 101_2 of the first active pattern 101. The fifth plurality of nanosheets NW5 may be spaced apart from the third plurality of nanosheets NW3 in the first horizontal direction DR1. The fifth plurality of nanosheets NW5 may be spaced apart from the fourth plurality of nanosheets NW4 in the second horizontal direction DR2.

The sixth, seventh, eighth, ninth and tenth plurality of nanosheets NW6, NW7, NW8, NW9 and NW10 may be disposed on the upper surface of the second active pattern 102. The sixth, seventh, eighth, ninth and tenth plurality of nanosheets NW6, NW7, NW8, NW9 and NW10 may be separated from the upper surface of the second active pattern 102 in the vertical direction DR3. For example, the sixth plurality of nanosheets NW6 may be disposed on the upper surface of the first portion 102_1 of the second active pattern 102. The sixth plurality of nanosheets NW6 may be separated from the second plurality of nanosheets NW2 in the second horizontal direction DR2. A seventh plurality of nanosheets NW7 may be disposed on the upper surface of the second portion 102_2 of the second active pattern 102. The seventh plurality of nanosheets NW7 may be separated from the sixth plurality of nanosheets NW6 in the second horizontal direction DR2. The eighth plurality of nanosheets NW8 may be disposed on the upper surfaces of the first, second and third portions 102_1, 102_2 and 102_3 of the second active pattern 102. In other words, the eighth plurality of nanosheets NW8 may overlap with each of the first, second and third portions 102_1, 102_2 and 102_3 of the second active pattern 102 in the vertical direction DR3. The eighth plurality of nanosheets NW8 may be spaced apart from each of the sixth and seventh plurality of nanosheets NW6 and NW7 in the first horizontal direction DR1. The eighth plurality of nanosheets NW8 may be spaced apart from the third plurality of nanosheets NW3 in the second horizontal direction DR2.

The ninth plurality of nanosheets NW9 may be disposed on the upper surface of the first portion 102_1 of the second active pattern 102. The ninth plurality of nanosheets NW9 may be spaced apart from the eighth plurality of nanosheets NW8 in the first horizontal direction DR1. The ninth plurality of nanosheets NW9 may be spaced apart from the fifth plurality of nanosheets NW5 in the second horizontal direction DR2. The tenth plurality of nanosheets NW10 may be disposed on the upper surface of the second portion 102_2 of the second active pattern 102. The tenth plurality of nanosheets NW10 may be spaced apart from the eighth plurality of nanosheets NW8 in the first horizontal direction DR1. The tenth plurality of nanosheets NW10 may be spaced apart from the ninth plurality of nanosheets NW9 in the second horizontal direction DR2.

For example, the width of each of the first plurality of nanosheets NW1, the second plurality of nanosheets NW2, the fourth plurality of nanosheets NW4, and the fifth plurality of nanosheets NW5, in the second horizontal direction DR2, may be the same. For example, the width of the third plurality of nanosheets NW3 in the second horizontal direction DR2 may be greater than the width of each of the first plurality of nanosheets NW1, the second plurality of nanosheets NW2, the fourth plurality of nanosheets NW4, and the fifth plurality of nanosheets NW5 in the second horizontal direction DR2. For example, the width of each of the sixth plurality of nanosheets NW6, the seventh plurality of nanosheets NW7, the ninth plurality of nanosheets NW9, and the tenth plurality of nanosheets NW10 in the second horizontal direction DR2 may be the same. For example, the width of the eighth plurality of nanosheets NW8 in the second horizontal direction DR2 may be greater than the width of each of the sixth plurality of nanosheets NW6, seventh plurality of nanosheets NW7, ninth plurality of nanosheets NW9, and tenth plurality of nanosheets NW10 in the second horizontal direction DR2. For example, the width of the eighth plurality of nanosheets NW8 in the second horizontal direction DR2 may equal to the width of the third plurality of nanosheets NW3 in the second horizontal direction DR2.

The first ground structure GS1 may be disposed on the upper surface of each of the first, second and third portions 101_1, 101_2 and 101_3 of the first active pattern 101. The first ground structure GS1 may include the third plurality of nanosheets NW3 and the first semiconductor layer 11. For example, the first semiconductor layer 11 may be disposed between the upper surface of the first active pattern 101 and the bottom surface of the lowermost nanosheets of the third plurality of nanosheets NW3. Additionally, the first semiconductor layer 11 may be disposed between adjacent third plurality of nanosheets NW3. In other words, the first ground structure GS1 may include the first semiconductor layer 11 and third plurality of nanosheets NW3 alternately stacked on the upper surface of each of the first, second and third portions 101_1, 101_2 and 101_3 of the first active pattern 101. For example, the upper surface of the first ground structure GS1 may be formed on the same plane as the upper surface of the uppermost nanosheet of the first plurality of nanosheets NW1.

For example, the sidewalls of the first semiconductor layer 11 in the second horizontal direction DR2 may have a continuous slope profile with the sidewalls of the third plurality of nanosheets NW3 in the second horizontal direction DR2. For example, the first semiconductor layer 11 may include silicon germanium (SiGe). In other words, the first ground structure GS1 may have a structure in which a first semiconductor layer 11 including silicon germanium (SiGe) and a third plurality of nanosheets NW3 including silicon (Si) are alternately stacked. For example, the first ground structure GS1 may include a doped n-type impurity. In other words, each of the third plurality of nanosheets NW3 and the first semiconductor layer 11 may include a doped n-type impurity. For example, the n-type impurity may include one of phosphorus (P), arsenic (As), antimony (Sb), and bismuth (Bi), but one or more example embodiments are not limited thereto.

The second ground structure GS2 may be disposed on the upper surface of each of the first, second and third portions 102_1, 102_2 and 102_3 of the second active pattern 102. The second ground structure GS2 may be spaced apart from the first ground structure GS1 in the second horizontal direction DR2. The second ground structure GS2 may include the eighth plurality of nanosheets NW8 and the second semiconductor layer 21. For example, the second semiconductor layer 21 may be disposed between the upper surface of the second active pattern 102 and the bottom surface of the lowermost nanosheet of the eighth plurality of nanosheets NW8. The second semiconductor layer 21 may also be disposed between adjacent eighth plurality of nanosheets NW8. In other words, the second ground structure GS2 may include second semiconductor layers 21 and eighth plurality of nanosheets NW8 alternately stacked on the upper surfaces of first, second and third portions 102_1, 102_2 and 102_3 of the second active pattern 102. For example, the upper surface of the second ground structure GS2 may be formed on the same plane as the upper surface of the uppermost nanosheet of the sixth plurality of nanosheets NW6.

For example, both sidewalls of the second semiconductor layer 21 in the second horizontal direction DR2 may have a continuous slope profile with both sidewalls of the eighth plurality of nanosheets NW8 in the second horizontal direction DR2. For example, the second semiconductor layer 21 may include silicon germanium (SiGe). In other words, the second ground structure GS2 may have a structure in which the second semiconductor layer 21 including silicon germanium (SiGe) and the plurality of eighth nanosheets NW8 including silicon (Si) are alternately stacked. For example, the second ground structure GS2 may include a doped p-type impurity. That is, each of the eighth plurality of nanosheets NW8 and the second semiconductor layer 21 may include a doped p-type impurity. For example, the p-type impurity may be boron (B) or carbon (C), but one or more example embodiments are not limited thereto.

The first gate electrode G1 may extend in the second horizontal direction DR2 on each of the first and second active patterns 101 and 102. For example, the first gate electrode G1 may overlap with each of the first and second portions 101_1 and 101_2 of the first active pattern 101 and each of the first and second portions 102_1 and 102_2 of the second active pattern 102 in the vertical direction DR3. However, the first gate electrode G1 may not overlap with either the third portion 101_3 of the first active pattern 101 or the third portion 102_3 of the second active pattern 102 in the vertical direction DR3. The first gate electrode G1 may surround each of the first plurality of nanosheets NW1, the second plurality of nanosheets NW2, the sixth plurality of nanosheets NW6, and the seventh plurality of nanosheets NW7.

The ground gate electrode GG may extend in the second horizontal direction DR2 on each of the first and second active patterns 101 and 102. The ground gate electrode GG may be spaced apart from the first gate electrode G1 in the first horizontal direction DR1. For example, the first gate electrode G1 may overlap with each of the first, second and third portions 101_1, 101_2 and 101_3 of the first active pattern 101 and each of the first, second and third portions 102_1, 102_2 and 102_3 of the second active pattern 102 in the vertical direction DR3. The ground gate electrode GG may cover both sidewalls and the upper surface of the first ground structure GS1 in the second horizontal direction. Additionally, the ground gate electrode GG may cover both sidewalls and the upper surface of the second ground structure GS2 in the second horizontal direction. For example, the bottom surface of the ground gate electrode GG may be in contact with the upper surface of the field insulating layer 105.

The second gate electrode G2 may extend in the second horizontal direction DR2 on each of the first and second active patterns 101 and 102. The second gate electrode G2 may be spaced apart from the ground gate electrode GG in the first horizontal direction DR1. For example, the second gate electrode G2 may overlap with each of the first and second portions 101_1 and 101_2 of the first active pattern 101 and each of the first and second portions 102_1 and 102_2 of the second active pattern 102 in the vertical direction DR3. However, the second gate electrode G2 may not overlap with either the third portion 101_3 of the first active pattern 101 or the third portion 102_3 of the second active pattern 102 in the vertical direction DR3. The second gate electrode G2 may surround each of the fourth plurality of nanosheets NW4, the fifth plurality of nanosheets NW5, the ninth plurality of nanosheets NW9, and the tenth plurality of nanosheets NW10.

For example, each of the first gate electrode G1, the second gate electrode G2, and the ground gate electrode GG may include the same material. For example, the first gate electrode G1, the second gate electrode G2, and the ground gate electrode GG may each include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) and any combinations thereof. The first gate electrode G1, the second gate electrode G2, and the ground gate electrode GG may include conductive metal oxides, conductive metal oxynitrides, or oxidized forms of the materials mentioned above.

The first gate spacer 111 may be disposed on both sidewalls of the first gate electrode G1 in the first horizontal direction DR1 on the upper surface of the uppermost nanosheets of each of the first plurality of nanosheets NW1, the second plurality of nanosheets NW2, the sixth plurality of nanosheets NW6, and the seventh plurality of nanosheets NW7. The first gate spacer 111 may be positioned on both sidewalls of the first gate electrode G1 in the first horizontal direction DR1 on the upper surface of the field insulating layer 105. The second gate spacer 112 may be disposed on both sidewalls of the ground gate electrode GG in the first horizontal direction DR1 on the upper surface of each of the first and second ground structures GS1 and GS2. In other words, the second gate spacer 112 may be disposed on both sidewalls of the ground gate electrode GG in the first horizontal direction DR1 on the upper surface of the uppermost nanosheets of each of the third plurality of nanosheets NW3 and the eighth plurality of nanosheets NW8. The second gate spacer 112 may be disposed on both sidewalls of the ground gate electrode GG in the first horizontal direction DR1 on the upper surface of the field insulating layer 105.

Additionally, gate spacers may also be disposed on both sidewalls of the second gate electrode G2 in the first horizontal direction DR1. For example, each of the first and second gate spacers 111 and 112 may include silicon nitride (SiN), silicon oxynitride (SiON), silicon oxide (SiO2), silicon carbonitride (SiCN), silicon oxycarbonitride (SiOCN), silicon boron nitride (SiBN), silicon oxyboron nitride (SiOBN), silicon oxycarbide (SiOC), or combinations thereof. However, one or more example embodiments are not limited thereto.

The first ground silicide layer 141 may be disposed between the first ground structure GS1 and the ground gate electrode GG. The first ground silicide layer 141 may be in contact with each of the first ground structure GS1 and the ground gate electrode GG. In other words, the first ground silicide layer 141 may be in contact with both sidewalls and the upper surface of the first ground structure GS1 in the second horizontal direction DR2. For example, both sidewalls of the first ground silicide layer 141 in the first horizontal direction DR1 may be in contact with the second gate spacer 112. The second ground silicide layer 142 may be disposed between the second ground structure GS2 and the ground gate electrode GG. The second ground silicide layer 142 may be in contact with each of the second ground structure GS2 and the ground gate electrode GG. In other words, the second ground silicide layer 142 may be in contact with both sidewalls and the upper surface of the second ground structure GS2 in the second horizontal direction DR2. Both sidewalls of the second ground silicide layer 142 in the first horizontal direction DR1 may be in contact with the second gate spacer 112.

For example, each of the first and second ground silicide layers 141 and 142 may be in contact with the upper surface of the field insulating layer 105. For example, each of the first and second ground silicide layers 141 and 142 may include a metal silicide. For example, each of the first and second ground silicide layers 141 and 142 may include titanium silicide (TiSi) or cobalt silicide (CoSi). In one or more example embodiments, each of the first and second ground silicide layers 141 and 142 may include a metal silicide formed by silicidation of one or more of tantalum (Ta), aluminum (Al), tungsten (W), ruthenium (Ru), copper (Cu), nickel (Ni), platinum (Pt), niobium (Nb), molybdenum (Mo), rhodium (Rh), palladium (Pd), iridium (Ir), osmium (Os), silver (Ag), gold (Au), zinc (Zn), or vanadium (V).

The first source/drain region SD1 may be disposed between the first gate electrode G1 and the ground gate electrode GG on the first active pattern 101. For example, the first source/drain region SD1 may be in contact with the sidewalls in the first horizontal direction DR1 of the first plurality of nanosheets NW1, the second plurality of nanosheets NW2, the third plurality of nanosheets NW3, and the first semiconductor layer 11, respectively. The second source/drain region SD2 may be disposed between the first gate electrode G1 and the ground gate electrode GG on the second active pattern 102. The second source/drain region SD2 may be in contact with the sidewalls in the first horizontal direction DR1 of the sixth plurality of nanosheets NW6, the seventh plurality of nanosheets NW7, the eighth plurality of nanosheets NW8, and the second semiconductor layer 21, respectively.

The gate insulating layer 121 may be disposed between the first gate electrode G1 and the first gate spacer 111. The gate insulating layer 121 may be disposed between the first gate electrode G1 and the first active pattern 101. The gate insulating layer 121 may be disposed between the first gate electrode G1 and the second active pattern 102. The gate insulating layer 121 may be disposed between the first gate electrode G1 and the field insulating layer 105. The gate insulating layer 121 may be disposed between the first gate electrode G1 and the first plurality of nanosheets NW1. The gate insulating layer 121 may be disposed between the first gate electrode G1 and the second plurality of nanosheets NW2. The gate insulating layer 121 may be disposed between the first gate electrode G1 and the sixth plurality of nanosheets NW6. The gate insulating layer 121 may be disposed between the first gate electrode G1 and the seventh plurality of nanosheets NW7. The gate insulating layer 121 may be disposed between the first gate electrode G1 and the first source/drain region SD1. The gate insulating layer 121 may be disposed between the first gate electrode G1 and the second source/drain region SD2. Also, the gate insulating layer may be disposed on the surface of the second gate electrode G2.

For example, the gate insulating layer 121 may include at least one of silicon oxide, silicon oxynitride, silicon nitride, or a high-k dielectric material having a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to one or more example embodiments may include a NC (Negative Capacitance) FET utilizing a negative capacitor. For example, the gate insulating layer 121 may include a ferroelectric material layer having ferroelectric properties and a paraelectric material layer having paraelectric properties.

The ferroelectric material layer may exhibit negative capacitance, while the paraelectric material layer may exhibit positive capacitance. For example, when two or more capacitors are connected in series and each of their capacitances has a positive value, the overall capacitance decreases relative to the capacitance of each individual capacitor. On the other hand, if the capacitances of at least one of the two or more capacitors connected in series has a negative value, the overall capacitance may be greater than the absolute value of each individual capacitance while still being positive.

When the ferroelectric material layer with negative capacitance and the paraelectric material layer with positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) combined with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer includes, the type of dopant included in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may include aluminum in a concentration of about 3 to 8 at % (atomic %). Here, the ratio of the dopant may be a ratio of aluminum relative to the sum of hafnium and aluminum.

If the dopant is silicon (Si), the ferroelectric material layer may include 2 to 10 at % of silicon. If the dopant is yttrium (Y), the ferroelectric material layer may include 2 to 10 at % of yttrium. If the dopant is gadolinium (Gd), the ferroelectric material layer may include 1 to 7 at % of gadolinium. If the dopant is zirconium (Zr), the ferroelectric material layer may include 50 to 80 at % of zirconium.

The paraelectric material layer may have paraelectric properties. The paraelectric material layer may include, for example, at least one or more of silicon oxide and metal oxides with a high-k dielectric constant. The metal oxides included in the paraelectric material layer may include, for example, at least one of hafnium oxide, zirconium oxide, and aluminum oxide, but is not limited to the aforementioned.

The ferroelectric material layer and the paraelectric material layer may include the same material. While the ferroelectric material layer may have ferroelectric properties, the paraelectric material layer may not have ferroelectric properties. For example, if both the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. For example, the thickness of the ferroelectric material layer may range from 0.5 to 10 nm, but one or more example embodiments are not limited thereto. Because the critical thickness for exhibiting ferroelectric properties may vary depending on the ferroelectric material, the thickness of the ferroelectric material layer also vary depending on the specific ferroelectric material used.

For example, the gate insulating layer 121 may include a single ferroelectric material layer. In another example, the gate insulating layer 121 may include multiple ferroelectric material layers spaced apart from each other. The gate insulating layer 121 may have a stacked structure in which multiple ferroelectric material layers and multiple paraelectric material layers are alternately stacked.

The first etching stop layer 150 may be positioned on the sidewall of each of the first and second gate spacers 111 and 112 in the first horizontal direction DR1. The first etching stop layer 150 may be positioned on the upper surface of each of the first and second source/drain regions SD1 and SD2. The first etching stop layer 150 may be positioned on both sidewalls of each of the first and second source/drain regions SD1 and SD2 in the second horizontal direction DR2. The first etching stop layer 150 may be positioned on the upper surface of the field insulating layer 105. For example, the first etching stop layer 150 may be formed conformally. For example, the first etching stop layer 150 may include at least one of aluminum oxide, aluminum nitride, hafnium oxide, zirconium oxide, silicon oxide, silicon nitride, silicon oxynitride, and low-k dielectric materials.

The first capping pattern 131 may extend in the second horizontal direction DR2 on the upper surface of each of the first gate spacer 111, the gate insulating layer 121, the first gate electrode G1, and the first etching stop layer 150. The first capping pattern 131 may be in contact with the upper surface of each of the first gate spacer 111, the gate insulating layer 121, the first gate electrode G1, and the first etching stop layer 150. The second capping pattern 132 may extend in the second horizontal direction DR2 on the upper surface of each of the second gate spacer 112, the ground gate electrode GG, and the first etching stop layer 150. The second capping pattern 132 may be in contact with the upper surface of each of the second gate spacer 112, the ground gate electrode GG, and the first etching stop layer 150. Also, a capping pattern may be disposed extending in the second horizontal direction DR2 on the upper surface of the second gate electrode G2.

For example, the upper surface of the first capping pattern 131 and the upper surface of the second capping pattern 132 may be formed on the same plane. For example, the upper surface of the first gate electrode G1 and the upper surface of the ground gate electrode GG may be formed on the same plane. For example, each of the first and second capping patterns 131 and 132 may include at least one of silicon nitride (SiN), silicon oxynitride (SiON), silicon oxide (SiO₂), silicon carbonitride (SiCN), silicon oxycarbonitride (SiOCN), and combinations thereof. However, one or more example embodiments are not limited thereto.

The first interlayer insulating layer 160 may be positioned on the first etching stop layer 150. The first interlayer insulating layer 160 may surround the sidewalls of each of the first and second capping patterns 131 and 132. For example, the upper surface of the first interlayer insulating layer 160 may be formed on the same plane as the upper surface of each of the first and second capping patterns 131 and 132. For example, the first interlayer insulating layer 160 may include at least one of silicon oxide, silicon nitride, silicon oxynitride, and low-k dielectric materials. Low-k dielectric materials include, for example, Fluorinated TetraEthylOrthoSilicate (FTEOS), Hydrogen SilsesQuioxane (HSQ), Bis-benzoCycloButene (BCB), Tetramethylorthosilicate (TMOS), Octamethylcyclotetrasiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, however, one or more example embodiments are not limited thereto.

The first gate cut GC1 may be disposed between the first portion 101_1 of the first active pattern 101 and the second portion 101_2 of the first active pattern 101. The third portion 101_3 of the first active pattern 101 may be spaced apart from the first gate cut GC1 in the first horizontal direction DR1. The second gate cut GC2 may be disposed between the first portion 102_1 of the second active pattern 102 and the second portion 102_2 of the second active pattern 102. The third portion 102_3 of the second active pattern 102 may be spaced apart from the second gate cut GC2 in the first horizontal direction DR1. Each of the first and second gate cuts GC1 and GC2 may penetrate the first capping pattern 131, the first gate electrode G1 and the gate insulating layer 121 in the vertical direction DR3 and may extend into the inside of the field insulating layer 105. Each of the first and second gate cuts GC1 and GC2 may separate the first gate electrode G1 in the second horizontal direction DR2.

The third gate cut GC3 may be disposed between the first ground structure GS1 and the second ground structure GS2. The third gate cut GC3 may be spaced apart from the first and second ground structures GS1 and GS2 in the second horizontal direction DR2. The third gate cut GC3 may penetrate the second capping pattern 132 and the ground gate electrode GG in the vertical direction DR3 and may extend into the inside of the field insulating layer 105. The third gate cut GC3 may separate the ground gate electrode GG in the second horizontal direction DR2.

The fourth gate cut GC4 may be disposed between the first portion 101_1 of the first active pattern 101 and the second portion 101_2 of the first active pattern 101. The fourth gate cut GC4 may be spaced apart from the third portion 101_3 of the first active pattern 101 in the first horizontal direction DR1. In other words, the third portion 101_3 of the first active pattern 101 may be disposed between the first gate cut GC1 and the fourth gate cut GC4. The fifth gate cut GC5 may be disposed between the first portion 102_1 of the second active pattern 102 and the second portion 102_2 of the second active pattern 102. The fifth gate cut GC5 may be spaced apart from the third portion 102_3 of the second active pattern 102 in the first horizontal direction DR1. In other words, the third portion 102_3 of the second active pattern 102 may be disposed between the second gate cut GC2 and the fifth gate cut GC5. Each of the fourth and fifth gate cuts GC4 and GC5 may separate the second gate electrode G2 in the second horizontal direction DR2.

For example, the upper surface of each of the first, second, third, fourth and fifth gate cuts GC1, GC2, GC3, GC4 and GC5 may be formed on the same plane as the upper surface of each of the first and second capping patterns 131 and 132. For example, each of the first, second, third, fourth and fifth gate cuts GC1, GC2, GC3, GC4 and GC5 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and combinations thereof.

The first source/drain contact CA1 may penetrate the first interlayer insulating layer 160 and the first etching stop layer 150 in the vertical direction DR3 to be electrically connected to the first source/drain region SD1. The second source/drain contact CA2 may penetrate the first interlayer insulating layer 160 and the first etching stop layer 150 in the vertical direction DR3 to be electrically connected to the second source/drain region SD2. For example, the upper surface of each of the first and second source/drain contacts CA1 and CA2 may be formed on the same plane as the upper surface of the first interlayer insulating layer 160. Each of the first and second source/drain contacts CA1 and CA2 may include a conductive material. The contact silicide layer SL may be disposed along the interface between the first source/drain contact CA1 and the first source/drain region SD1. Additionally, the contact silicide layer SL may be disposed along the interface between the second source/drain contact CA2 and the second source/drain region SD2. For example, the contact silicide layer SL may include a metal silicide material.

The second etching stop layer 170 may be disposed on the upper surfaces of the first interlayer insulating layer 160, the first and second capping patterns 131 and 132, the first and second source/drain contacts CA1 and CA2, and the first, second, third, fourth and fifth gate cuts GC1, GC2, GC3, GC4 and GC5, respectively. For example, the second etching stop layer 170 may be formed conformally. In FIGS. 2, 3, 4 and 5, the second etching stop layer 170 is shown as being formed as a single layer, but one or more example embodiments are not limited thereto. In one or more example embodiments, the second etching stop layer 170 may be formed as a multi-layer. For example, the second etching stop layer 170 may include at least one of aluminum oxide, aluminum nitride, hafnium oxide, zirconium oxide, silicon oxide, silicon nitride, silicon oxynitride, and low-k dielectric materials. The second interlayer insulating layer 180 may be disposed on the second etching stop layer 170. For example, the second interlayer insulating layer 180 may include at least one of silicon oxide, silicon nitride, silicon oxynitride, and low-k dielectric materials.

Each of the first, second and third gate contacts CB1, CB2, and CB3 may penetrate the second interlayer insulating layer 180, the second etching stop layer 170, and the first capping pattern 131 in the vertical direction DR3 to be connected to the first gate electrode G1. For example, the first gate cut GC1 may be disposed between the first gate contact CB1 and the second gate contact CB2. The second gate cut GC2 may be disposed between the second gate contact CB2 and the third gate contact CB3. Each of the first and second ground gate contacts GCB1 and GCB2 may penetrate the second interlayer insulating layer 180, the second etching stop layer 170, and the second capping pattern 132 in the vertical direction DR3 to be connected to the ground gate electrode GG. For example, the third gate cut GC3 may be disposed between the first ground gate contact GCB1 and the second ground gate contact GCB2.

For example, the upper surface of each of the first, second and third gate contacts CB1, CB2, and CB3 and each of the first and second ground gate contacts GCB1 and GCB2 may be formed on the same plane as the upper surface of the second interlayer insulating layer 180. Each of the first and second source/drain contacts CA1 and CA2 and the first and second ground gate contacts GCB1 and GCB2 may include a conductive material. For example, the substrate 100 in the PMOS region I may be grounded through the first active pattern 101, the first ground structure GS1, the first ground silicide layer 141, the ground gate electrode GG, and the first ground gate contact GCB1. Additionally, the substrate 100 in the NMOS region II may be grounded through the second active pattern 102, the second ground structure GS2, the second ground silicide layer 142, the ground gate electrode GG, and the second ground gate contact GCB2.

The first via V1 may penetrate the second interlayer insulating layer 180 and the second etching stop layer 170 in the vertical direction DR3 to be connected to the first source/drain contact CA1. The second via V2 may penetrate the second interlayer insulating layer 180 and the second etching stop layer 170 in the vertical direction DR3 to be connected to the second source/drain contact CA2. Each of the first and second vias V1 and V2 may include a conductive material.

In a semiconductor device according to one or more example embodiments, a ground gate electrode GG may be positioned between two gate electrodes G1 and G2, and a ground structure GS1 including semiconductor layers 11 and a plurality of nanosheets NW3 alternately stacked beneath the ground gate electrode GG may be positioned. The semiconductor device according to one or more example embodiments may ground the substrate 100 to the ground through ground structures GS1 and GS2 and ground gate electrode GG. In the semiconductor device according to one or more example embodiments, the configuration for grounding the substrate 100 may not be disposed in a separate region, such as the edge of the substrate 100. Instead, the ground gate electrode GG may be formed in the region where the dummy gate DG2 is disposed in the fabrication process, thereby enhancing the overall integration of the semiconductor device. Additionally, the semiconductor device according to one or more example embodiments may reduce the resistance of the route for grounding the substrate 100 by forming the width of a plurality of nanosheets NW3 disposed beneath the ground gate electrode GG to be greater than the width of other plurality of nanosheets NW1 disposed beneath the gate electrode G1.

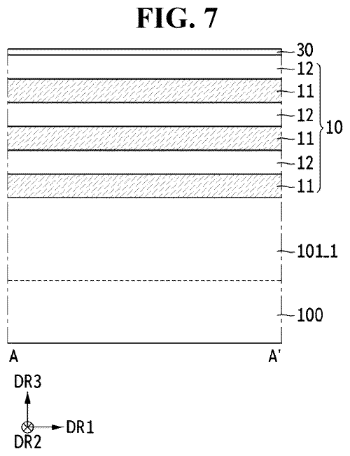

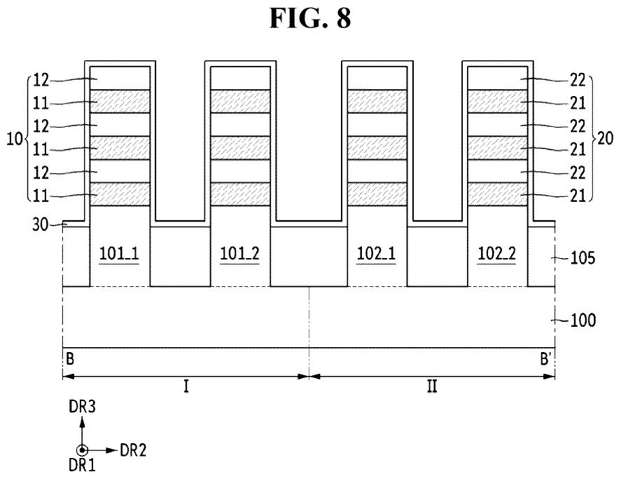

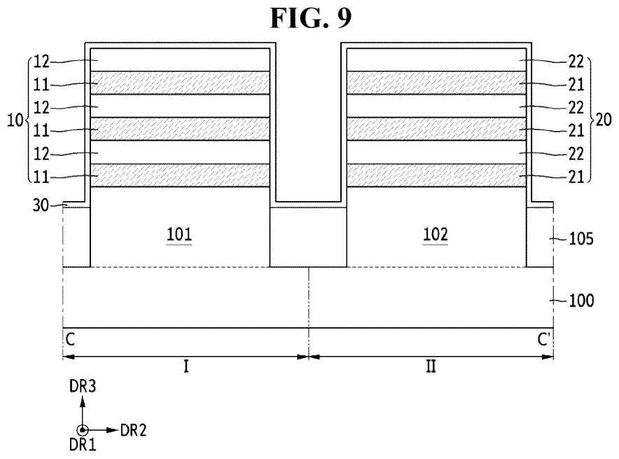

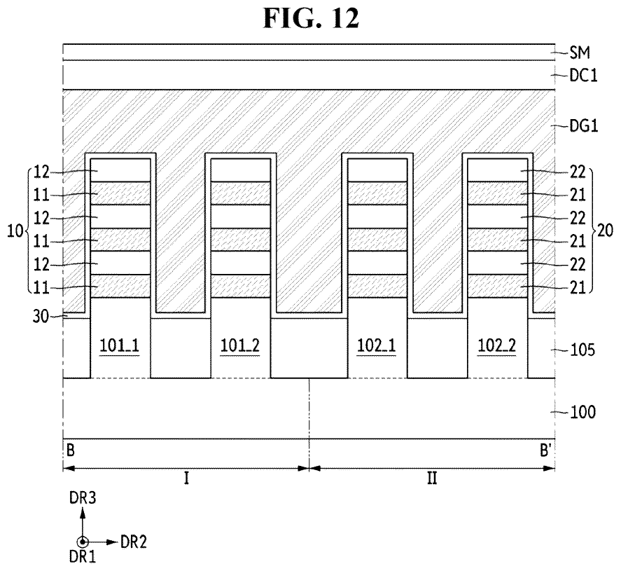

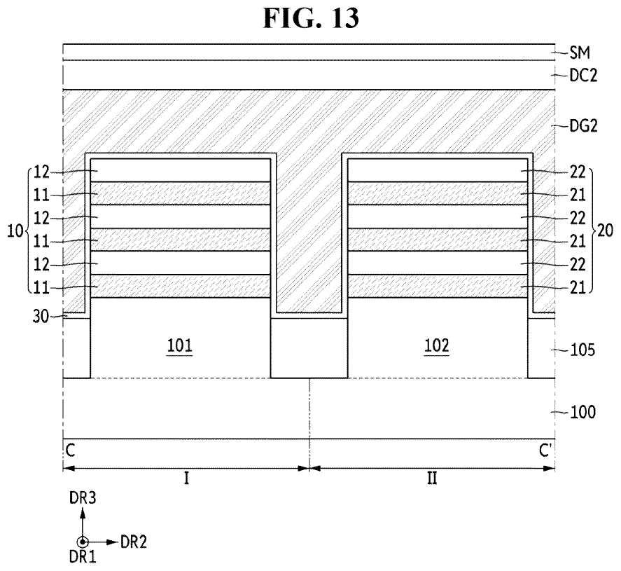

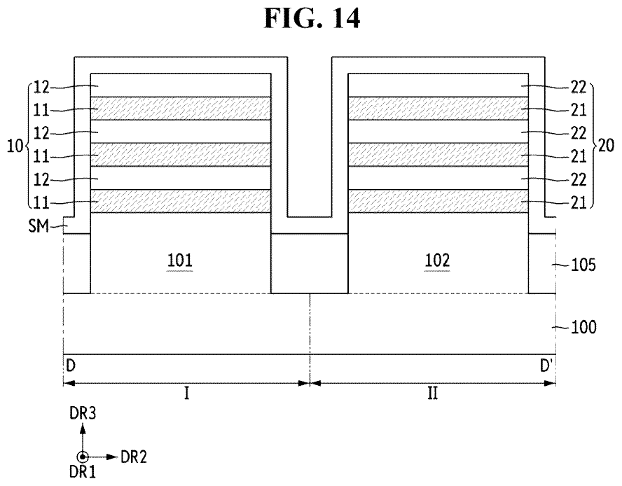

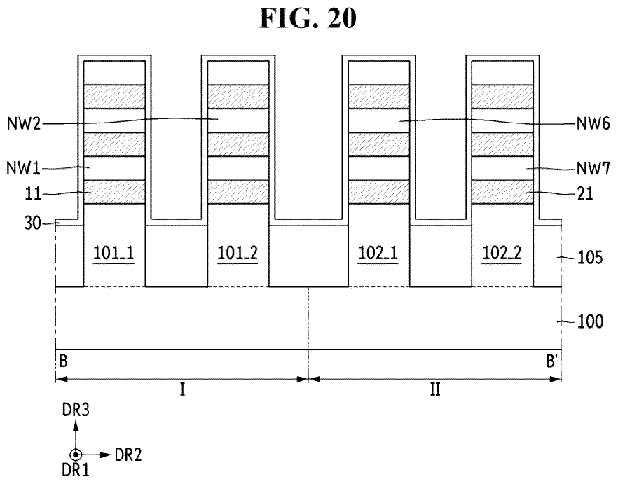

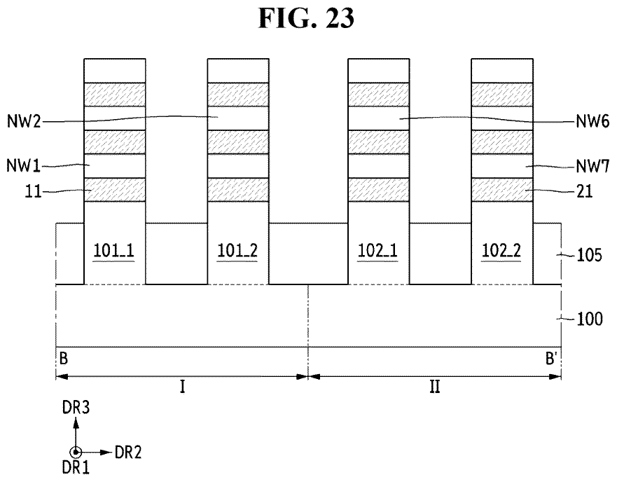

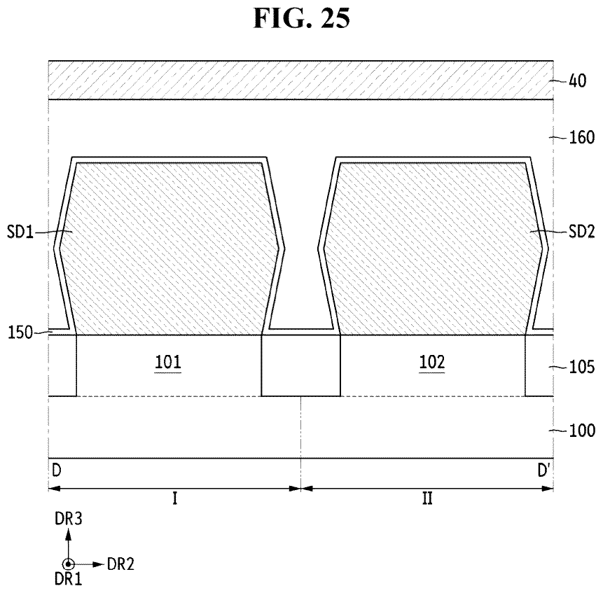

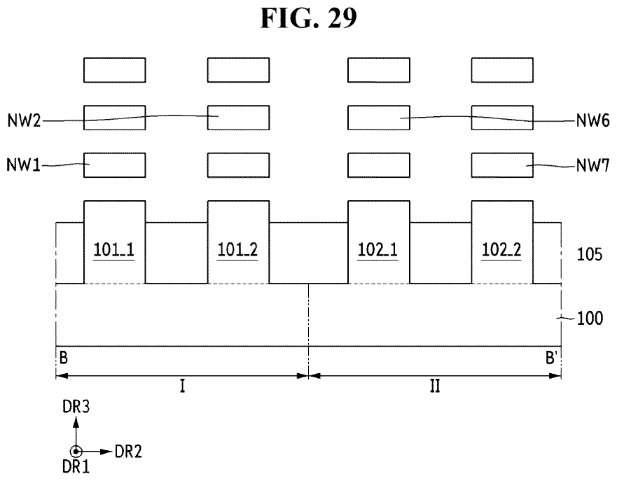

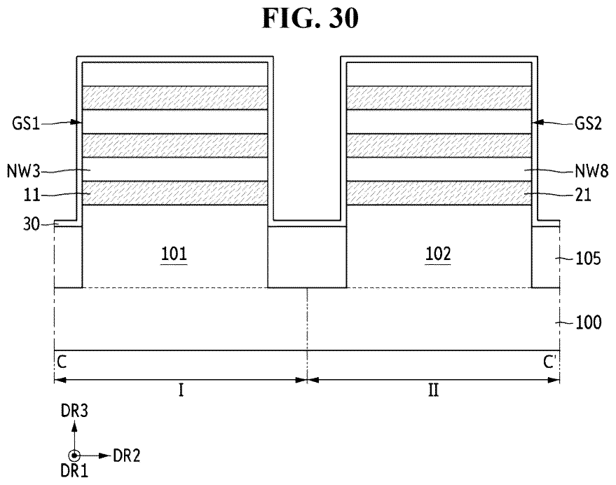

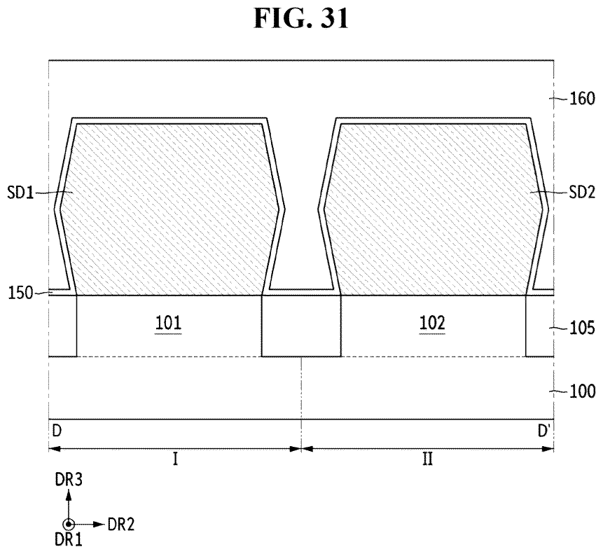

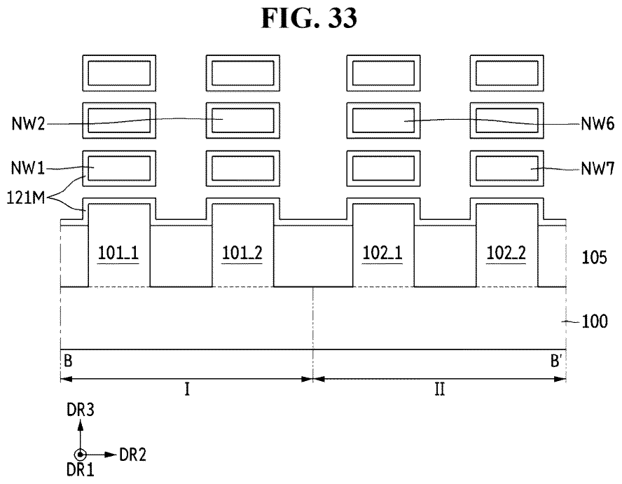

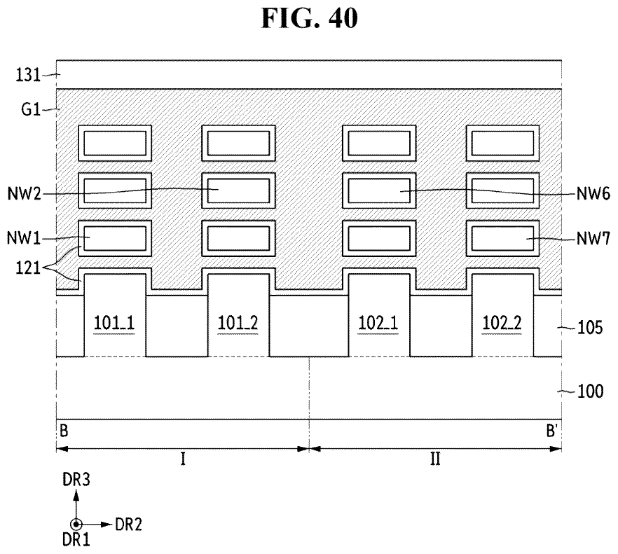

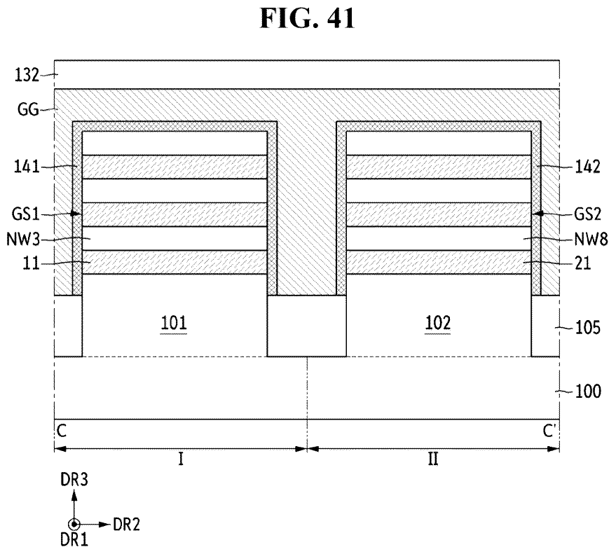

Hereinafter, the method for fabricating the semiconductor device according to one or more example embodiments is described with reference to FIGS. 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40 and 41.

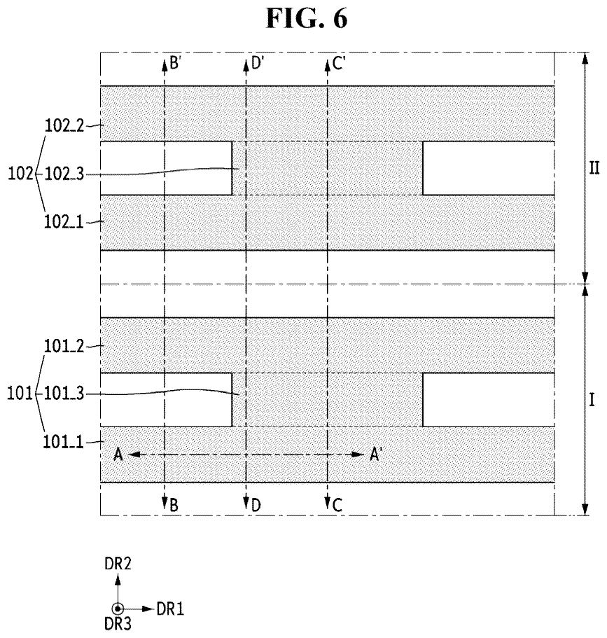

FIGS. 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40 and 41 are intermediate stage diagrams for explaining the semiconductor device according to one or more example embodiments.

Referring to FIGS. 6, 7, 8 and 9, a first stacked structure 10 and a second stacked structure 20 may each be formed on a substrate 100. The first stacked structure 10 may be formed on the substrate 100 in the PMOS region I. The second stacked structure 20 may be formed on the substrate 100 in the NMOS region II. For example, the first stacked structure 10 may include the first semiconductor layer 11 and the third semiconductor layer 12 alternately stacked on the substrate 100. Additionally, the second stacked structure 20 may include the second semiconductor layer 21 and the fourth semiconductor layer 22 alternately stacked on the substrate 100.

For example, the first semiconductor layer 11 may be formed at the lowermost portion of the first stacked structure 10, and the third semiconductor layer 12 may be formed at the uppermost portion of the first stacked structure 10. The second semiconductor layer 21 may be formed at the lowermost portion of the second stacked structure 20, and the fourth semiconductor layer 22 may be formed at the uppermost portion of the second stacked structure 20. For example, the first semiconductor layer 11 and the second semiconductor layer 21 may be positioned at the same level. Additionally, the third semiconductor layer 12 and the fourth semiconductor layer 22 may be positioned at the same level. For example, the first semiconductor layer 11 and the second semiconductor layer 21 may include silicon germanium (SiGe), and the third semiconductor layer 12 and the fourth semiconductor layer 22 may include silicon (Si).

Subsequently, a portion of each of the first and second stacked structures 10 and 20 may be etched. While the first and second stacked structures 10 and 20 are each being etched, a portion of the substrate 100 may also be etched. Through this etching process, the first active pattern 101 may be defined beneath the first stacked structure 10 on the upper surface of the substrate 100 in the PMOS region I, and the second active pattern 102 may be defined beneath the second stacked structure 20 on the upper surface of the substrate 100 in the NMOS region II. Each of the first and second active patterns 101 and 102 may extend in the first horizontal direction DR1. The second active pattern 102 may be spaced from the first active pattern 101 in the second horizontal direction DR2.

For example, the first active pattern 101 may include the first, second and third portions 101_1, 101_2 and 101_3. Each of the first portion 101_1 of the first active pattern 101 and the second portion 101_2 of the first active pattern 101 may extend in the first horizontal direction DR1 on the upper surface of the substrate 100 in the PMOS region I. The third portion 101_3 of the first active pattern 101 may be positioned between the first portion 101_1 of the first active pattern 101 and the second portion 101_2 of the first active pattern 101. The third portion 101_3 of the first active pattern 101 may connect the first portion 101_1 of the first active pattern 101 and the second portion 101_2 of the first active pattern 101.

For example, the second active pattern 102 may include the first, second and third portions 102_1, 102_2 and 102_3. Each of the first portion 102_1 of the second active pattern 102 and the second portion 102_2 of the second active pattern 102 may extend in the first horizontal direction DR1 on the upper surface of the substrate 100 in the NMOS region II. For example, the first portion 102_1 of the second active pattern 102 may be spaced apart from the second portion 101_2 of the first active pattern 101 in the second horizontal direction DR2. The third portion 102_3 of the second active pattern 102 may be positioned between the first portion 102_1 of the second active pattern 102 and the second portion 102_2 of the second active pattern 102. The third portion 102_3 of the second active pattern 102 may connect the first portion 102_1 of the second active pattern 102 and the second portion 102_2 of the second active pattern 102.

Subsequently, the field insulating layer 105 may be formed on the upper surface of the substrate 100. The field insulating layer 105 may surround the sidewalls of the first and second active patterns 101 and 102, respectively. For example, the upper surface of each of the first and second active patterns 101 and 102 may be positioned higher than the upper surface of the field insulating layer 105. Then, a pad oxide layer 30 may be formed to cover the upper surface of the field insulating layer 105, the exposed sidewalls of each of the first and second active patterns 101 and 102, the sidewalls and upper surface of each of the first and second stacked structures 10 and 20. For example, the pad oxide layer 30 may be formed conformally. For example, the pad oxide layer 30 may include silicon oxide (SiO2).

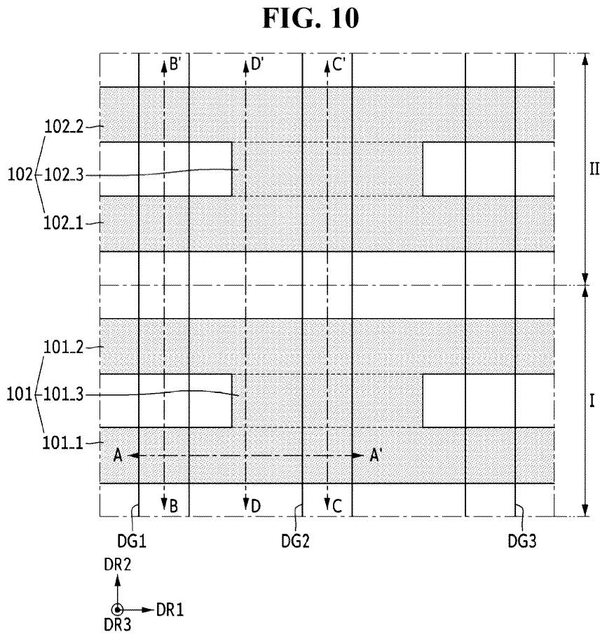

Referring to FIGS. 10, 11, 12, 13 and 14, first, second and third dummy gates DG1, DG2 and DG3 and first and second dummy capping patterns DC1 and DC2 extending in the second horizontal direction DR2 may be formed on the pad oxide layer 30 over the first and second stacked structure 10 and 20 and the field insulating layer 105. For example, the second dummy gate DG2 may be spaced apart from the first dummy gate DG1 in the first horizontal direction DR1. The third dummy gate DG3 may be spaced apart from the second dummy gate DG2 in the first horizontal direction DR1. The first dummy capping pattern DC1 may be positioned on the first dummy gate DG1, and the second dummy capping pattern DC2 may be positioned on the second dummy gate DG2. The dummy capping pattern may be positioned on the third dummy gate DG3.

For example, the first dummy gate DG1 may overlap with each of the first and second portions 101_1 and 101_2 of the first active pattern 101 and the first and second portions 102_1 and 102_2 of the second active pattern 102 in the vertical direction DR3. The second dummy gate DG2 may overlap with each of the first, second and third portions 101_1, 101_2 and 101_3 of the first active pattern 101 and the first, second and third portions 102_1, 102_2 and 102_3 of the second active pattern 102 in the vertical direction DR3. The third dummy gate DG3 may overlap with each of the first and second portions 101_1 and 101_2 of the first active pattern 101 and the first and second portions 102_1 and 102_2 of the second active pattern 102 in the vertical direction DR3.

While the first, second and third dummy gates DG1, DG2 and DG3 and the first and second dummy capping patterns DC1 and DC2 are being formed, the remaining portion of the pad oxide layer 30 except for the portion overlapping with each of the first, second and third dummy gates DG1, DG2 and DG3 in the vertical direction DR3 on the substrate 100 may be removed. Subsequently, a spacer material layer SM may be formed to cover the sidewalls of each of the first, second and third dummy gates DG1, DG2 and DG3, the sidewalls and upper surface of each of the first and second dummy capping patterns DC1 and DC2, the exposed sidewalls and upper surface of each of the first and second stacked structures 10 and 20, and the upper surface of the field insulating layer 105. For example, the spacer material layer SM may be formed conformally. For example, the spacer material layer SM may include at least one or more of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and combinations thereof.

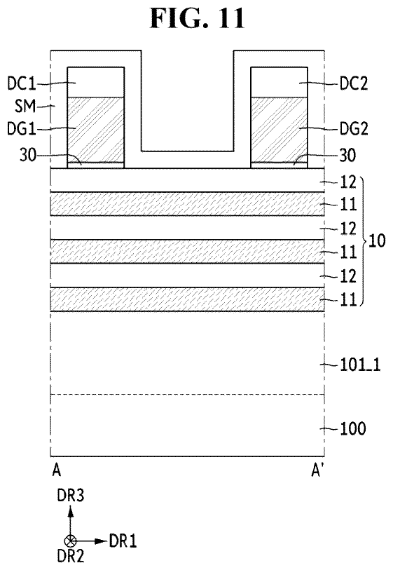

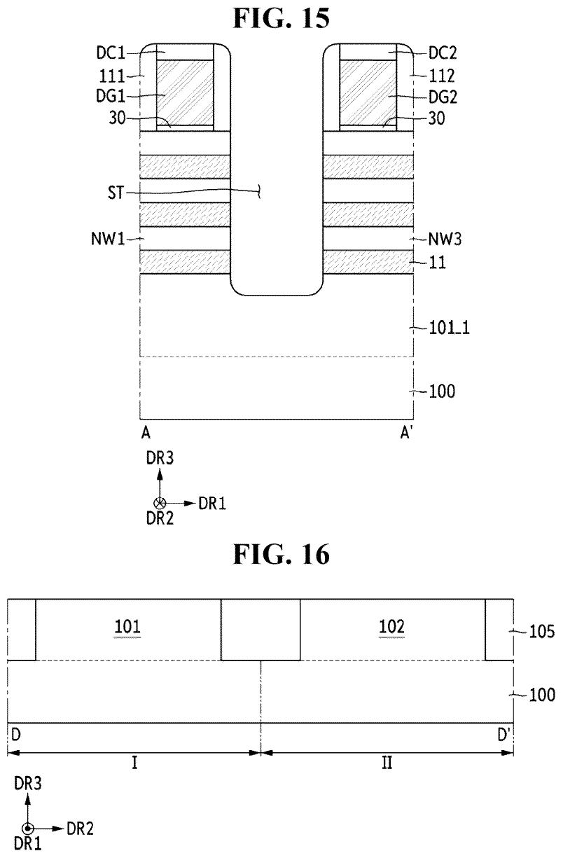

Referring to FIGS. 15 and 16, the first and second dummy gates DG1 and DG2 and the first and second dummy capping patterns DC1 and DC2 may be used as masks to etch the first and second stacked structures (see FIGS. 11, 12, 13 and 14) to form a source/drain trench ST. For example, the source/drain trench ST may be formed between the first dummy gate DG1 and the second dummy gate DG2 on each of the first active pattern 101 and the second active pattern 102. For example, during the formation of the source/drain trench ST, a portion of the spacer material layer SM (see FIGS. 11, 12, 13 and 14) formed on the upper surface of each of the first and second dummy capping patterns DC1 and DC2 and a portion of each of the first and second dummy capping patterns DC1 and DC2 may be etched. The spacer material layer SM (see FIGS. 11, 12, 13 and 14) remaining on the sidewalls of each of the first and second dummy capping patterns DC1 and DC2 and the first and second dummy gates DG1 and DG2 may be defined as the first and second gate spacers 111 and 112.

For example, after the source/drain trench ST is formed, the third semiconductor layer 12 (see FIGS. 11, 12, 13 and 14) remaining at the overlap between the first active pattern 101 and each of the first, second and third dummy gates DG1, DG2 and DG3 (see FIG. 10) may be defined as the first, second, third, fourth and fifth plurality nanosheets NW1, NW2, NW3, NW4 and NW5 (see FIGS. 1, 2, 3 and 4). Additionally, after the source/drain trench ST is formed, the fourth semiconductor layer 22 (see FIGS. 11, 12, 13 and 14) remaining at the overlap between the second active pattern 102 and each of the first, second and third dummy gates DG1, DG2 and DG3 (see FIG. 10) may be defined as the sixth, seventh, eighth, ninth and tenth plurality of nanosheets NW6, NW7, NW8, NW9 and NW10 (see FIGS. 1, 2, 3 and 4).

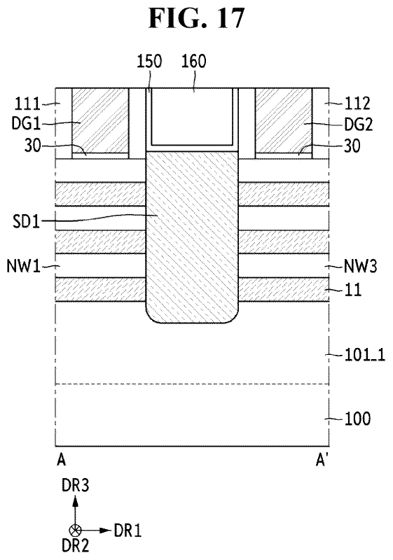

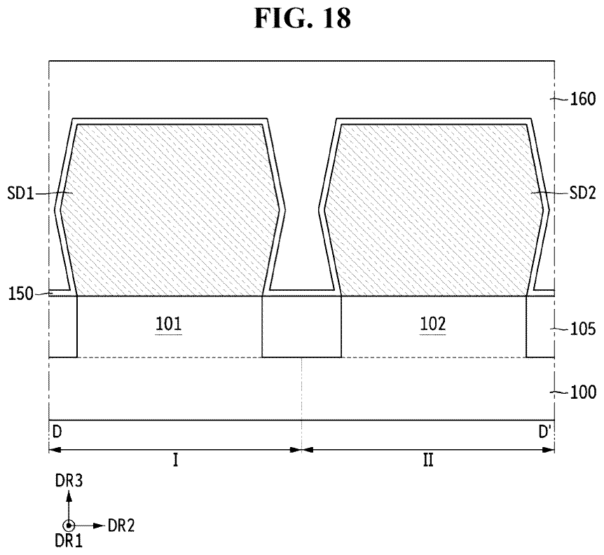

Referring to FIGS. 17 and 18, the first source/drain region SD1 may be formed inside the source/drain trench ST (see FIG. 15) on the first active pattern 101, and the second source/drain region SD2 may be formed inside the source/drain trench on the second active pattern 102. Subsequently, the first etching stop layer 150 may be formed on the upper surface of the exposed field insulating layer 105, on the sidewalls of the exposed first and second gate spacers 111 and 112, on the upper surfaces of the exposed first and second dummy capping patterns DC1 and DC2 (see FIG. 15), and on the surfaces of the exposed first and second source/drain regions SD1 and SD2. Then, the first interlayer insulating layer 160 may be formed on the first etching stop layer 150. Then, the planarization process is performed so that the upper surface of each of the first and second dummy gates DG1 and DG2 may be exposed.

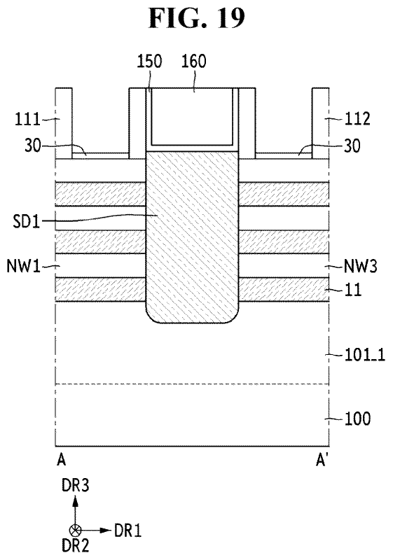

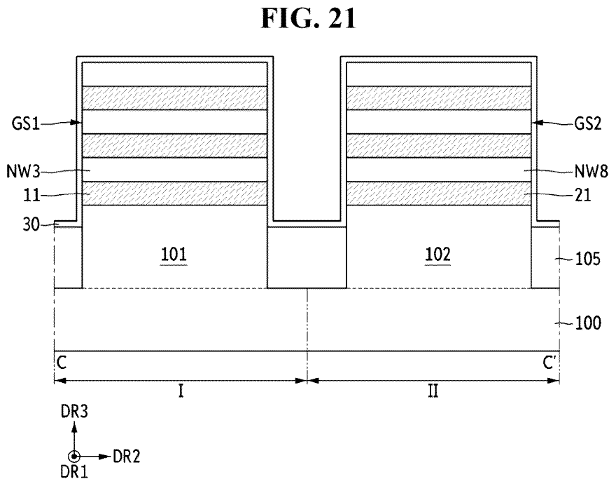

Referring to FIGS. 19, 20 and 21, the first and second dummy gates DG1 and DG2 may be etched. In FIG. 21, the first semiconductor layer 11 and the third plurality of nanosheets NW3 alternately stacked may be defined as the first ground structure GS1, and the second semiconductor layer 21 and the eighth plurality of nanosheets NW8 alternately stacked may be defined as the second ground structure GS2.

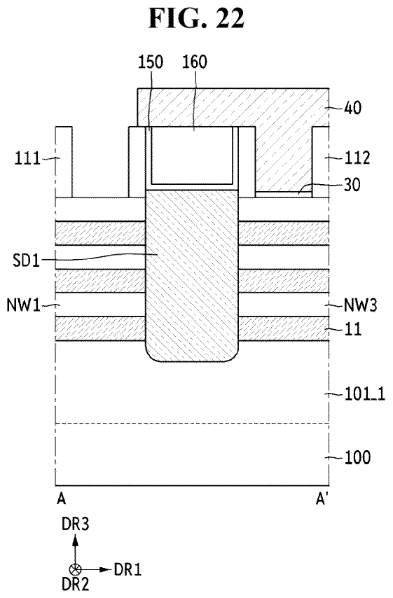

Referring to FIGS. 22, 23, 24 and 25, a first protective layer 40 may be formed to expose the region between the first gate spacers 111. For example, the first protective layer 40 may include a spin-on hardmask (SOH). Subsequently, the pad oxide layer 30 exposed between the first gate spacers 111 may be etched.

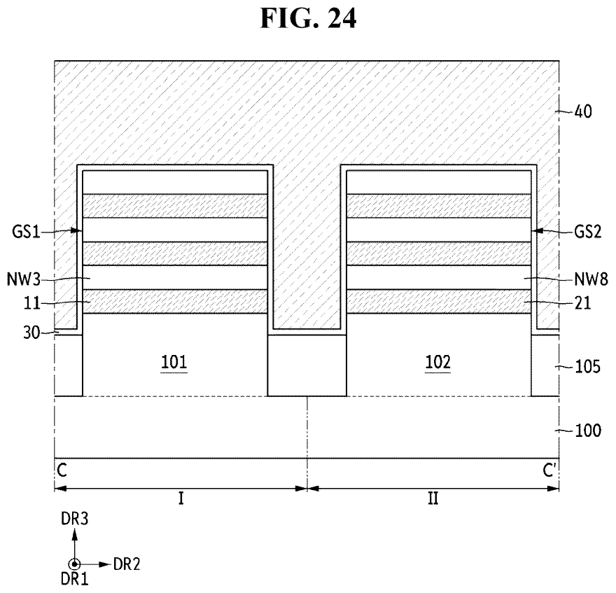

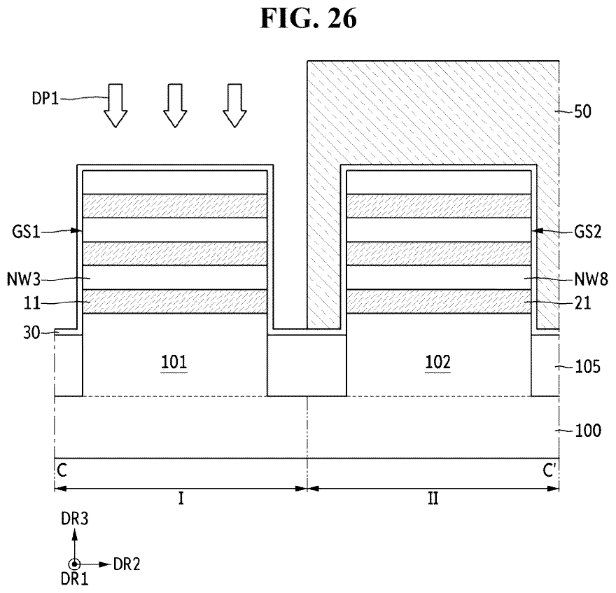

Referring to FIG. 26, the first protective layer 40 (see FIG. 24) may be removed. Subsequently, a second protective layer 50 may be formed in the remaining region except for the region where the first ground structure GS1 has been formed. For example, the second protective layer 50 may include a spin-on hardmask (SOH). Subsequently, a first doping process DP1 may be performed to dope the first ground structure GS1 with n-type impurities. Consequently, n-type impurities may be doped into the first ground structure GS1.

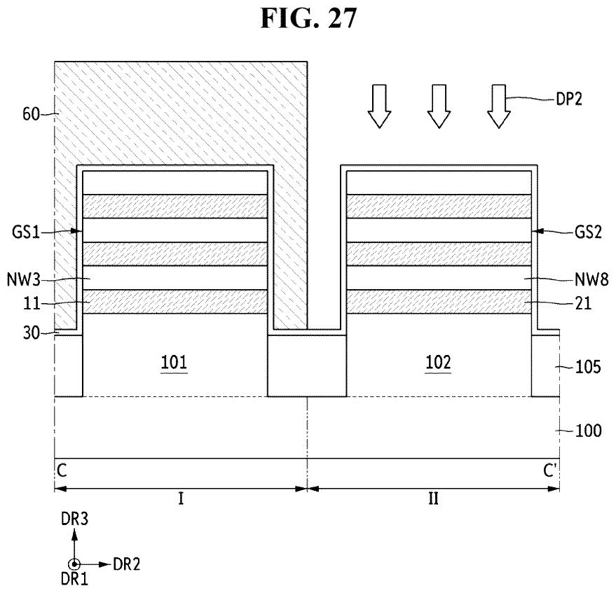

Referring to FIG. 27, the second protective layer 50 (see FIG. 26) may be removed. Subsequently, a third protective layer 60 may be formed in the remaining regions except for the region where the second ground structure GS2 is formed. For example, the third protective layer 60 may include a spin-on hardmask (SOH). Subsequently, a second doping process DP2 may be performed to dope the second ground structure GS2 with p-type impurities. As a result, p-type impurities may be doped into the second ground structure GS2.

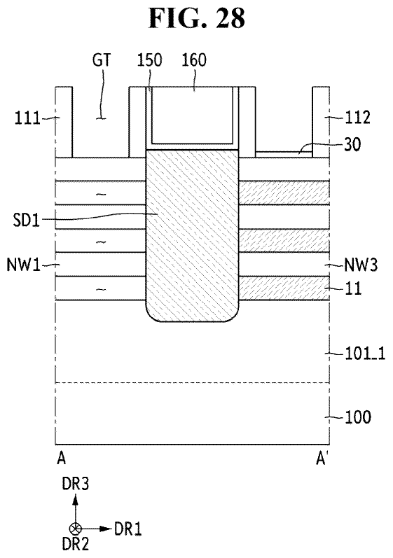

Referring to FIGS. 28, 29, 30 and 31, the third protective layer 60 (see FIG. 27) may be removed. Subsequently, the first semiconductor layer 11 and the second semiconductor layer 21, each of which is disposed beneath the first gate spacer 111, may be etched. However, the first semiconductor layer 11 and the second semiconductor layer 21, each of which is disposed beneath the second gate spacer 112, are protected by the pad oxide layer 30 and may not be etched. For example, the region between the first gate spacers 111 and the portion where each of the first semiconductor layer 11 and the second semiconductor layer 21 is etched may be defined as the gate trench GT.

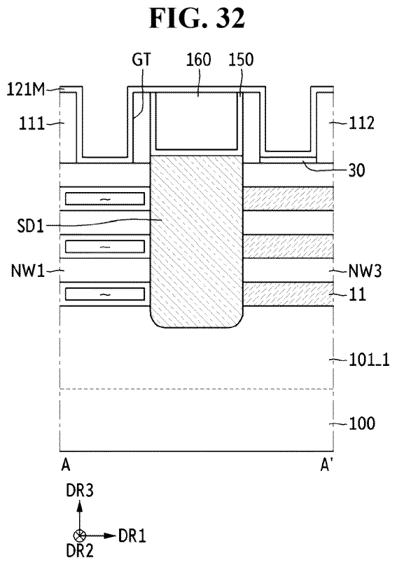

Referring to FIGS. 32, 33 and 34, a gate insulating material layer 121M may be formed along the exposed surface inside the gate trench GT. For example, the gate insulating material layer 121M may also be formed on the upper surface of the first etching stop layer 150, the upper surface of the first interlayer insulating layer 160, and the exposed surface of each of the first and second gate spacers 111 and 112. Additionally, the gate insulating material layer 121M may also be formed on the pad oxide layer 30 between the second gate spacers 112. For example, the gate insulating material layer 121M may be formed conformally. For example, the gate insulating material layer 121M may include the same material as the gate insulating layer 121 shown in FIGS. 2 and 3.

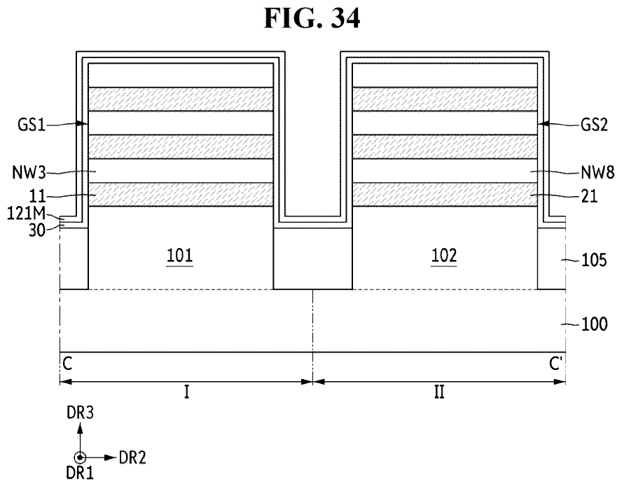

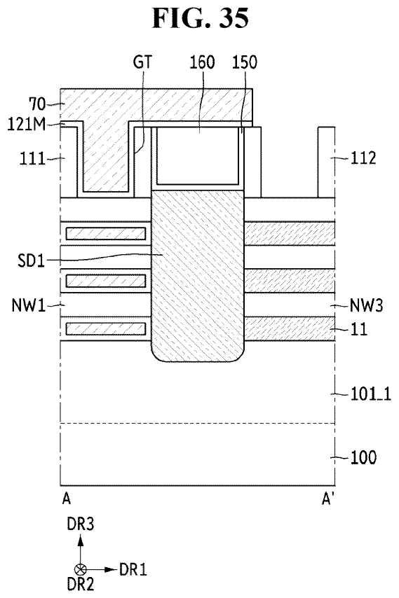

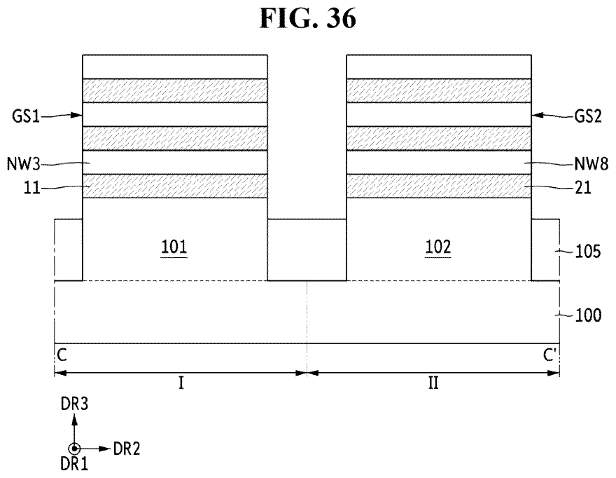

Referring to FIGS. 35 and 36, a fourth protective layer 70 may be formed on the gate insulating material layer 121M. The fourth protective layer 70 may be formed in the remaining region, except for the region where the first and second ground structures GS1 and GS2 are formed. For example, the fourth protective layer 70 may include a spin-on hardmask (SOH). Subsequently, the gate insulating material layer 121M and the pad oxide layer 30 (see FIGS. 32 and 34) in the portion where the fourth protective layer 70 is not formed may be etched. Consequently, both sidewalls and upper surface of each of the first and second ground structures GS1 and GS2 in the second horizontal direction DR2 may be exposed.

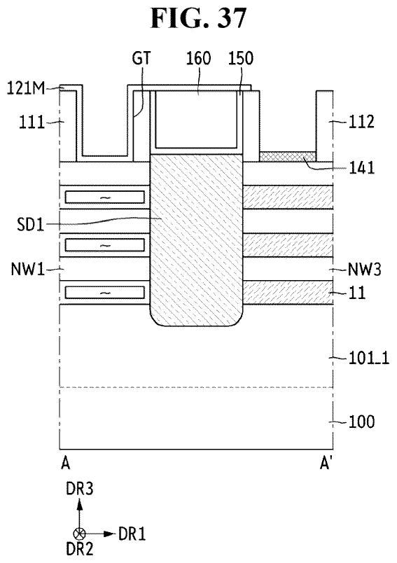

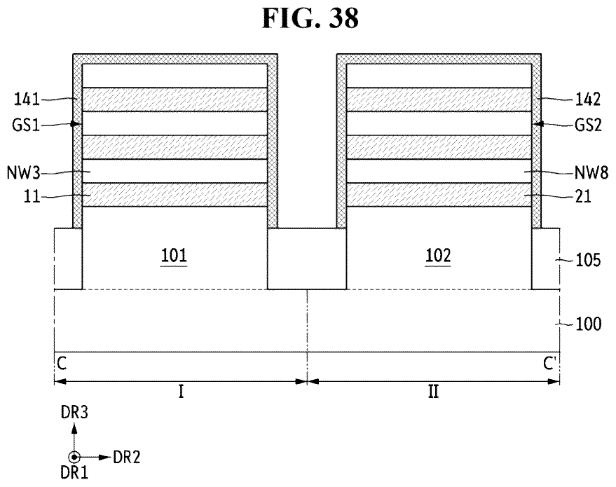

Referring to FIGS. 37 and 38, the fourth protective layer 70 (see FIG. 35) may be removed. Subsequently, the first ground silicide layer 141 may be formed on both sidewalls and the upper surface of the first ground structure GS1 in the second horizontal direction DR2. The first ground silicide layer 141 may be in contact with both sidewalls and the upper surface of the first ground structure GS1 in the second horizontal direction DR2. Additionally, the second ground silicide layer 142 may be formed on both sidewalls and the upper surface of the second ground structure GS2 in the second horizontal direction DR2. For example, the second ground silicide layer 142 may be in contact with both sidewalls and the upper surface of the second ground structure GS2 in the second horizontal direction DR2. For example, the sidewalls of each of the first and second ground silicide layers 141 and 142 in the first horizontal direction DR1 may be in contact with the second gate spacer 112. For example, the bottom surfaces of the first and second ground silicide layers 141 and 142 may each be in contact with the field insulating layer 105.

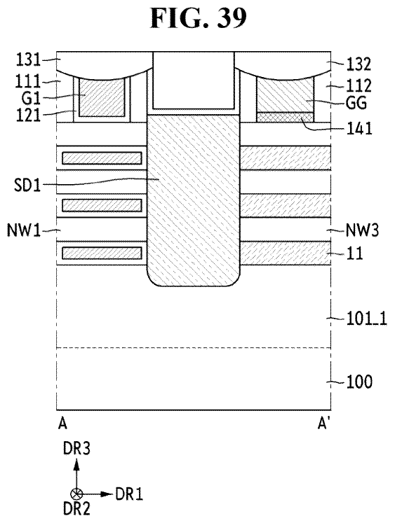

Referring to FIGS. 39, 40 and 41, the first gate electrode G1 may be formed inside the gate trench GT. For example, the first gate electrode G1 may surround the first plurality of nanosheets NW1, the second plurality of nanosheets NW2, the sixth plurality of nanosheets NW6, and the seventh plurality of nanosheets NW7. Additionally, the ground gate electrode GG may be formed between the second gate spacers 112. For example, the ground gate electrode GG may be in contact with each of the first and second ground silicide layers 141 and 142. Also, the ground gate electrode GG may be in contact with the upper surface of the field insulating layer 105. For example, both sidewalls of the ground gate electrode GG in the first horizontal direction DR1 may be in contact with the second gate spacer 112. For example, the first gate electrode G1 and the ground gate electrode GG may be formed through the same fabrication process. Then, the first capping pattern 131 may be formed on the upper surface of the first gate electrode G1, and the second capping pattern 132 may be formed on the upper surface of the ground gate electrode GG.

Referring to FIGS. 1, 2, 3, 4 and 5, the first and second source/drain contacts CA1 and CA2, the contact silicide layer SL, and the first, second, third, fourth and fifth gate cuts GC1, GC2, GC3, GC4 and GC5 may be formed. Subsequently, after the second etching stop layer 170 and the second interlayer insulating layer 180 are formed, the first, second and third gate contacts CB1, CB2, and CB3, the first and second ground gate contacts GCB1 and GCB2, and the first and second vias V1 and V2 may be formed. Through this fabrication process, the semiconductor devices shown in FIGS. 1, 2, 3, 4 and 5 may be fabricated.

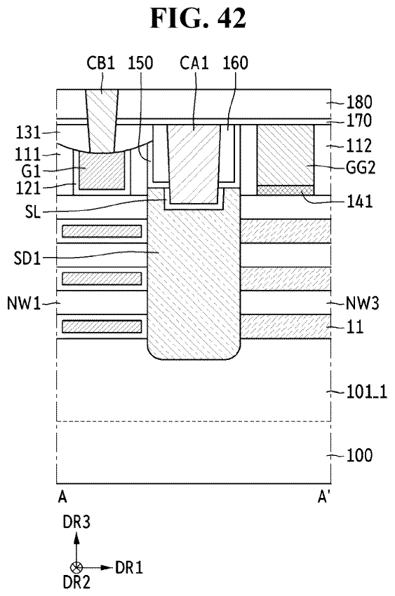

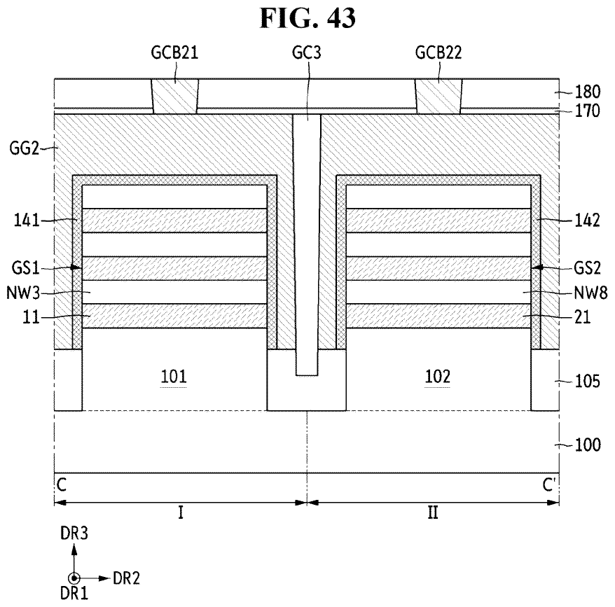

Hereinafter, the semiconductor device according to one or more example embodiments is described with reference to FIG. 42 and FIG. 43. The description focuses on the differences from the semiconductor device shown in FIGS. 1, 2, 3, 4 and 5, according to one or more example embodiments.

FIGS. 42 and 43 are cross-sectional views for explaining the semiconductor device according to one or more example embodiments.

Referring to FIGS. 42 and 43, in the semiconductor device according to one or more example embodiments, the upper surface of the ground gate electrode GG2 may be formed higher than the upper surface of the first gate electrode G1.

For example, the upper surface of the ground gate electrode GG2 may be in contact with the second etching stop layer 170. The upper surface of the ground gate electrode GG2 may be formed on the same plane as the upper surface of the first capping pattern 131. Each of the first and second ground gate contacts GCB21 and GCB22 may penetrate the second interlayer insulating layer 180 and the second etching stop layer 170 in the vertical direction DR3 to be connected to the ground gate electrode GG2. For example, the third gate cut GC3 may be disposed between the first ground gate contact GCB21 and the second ground gate contact GCB22.

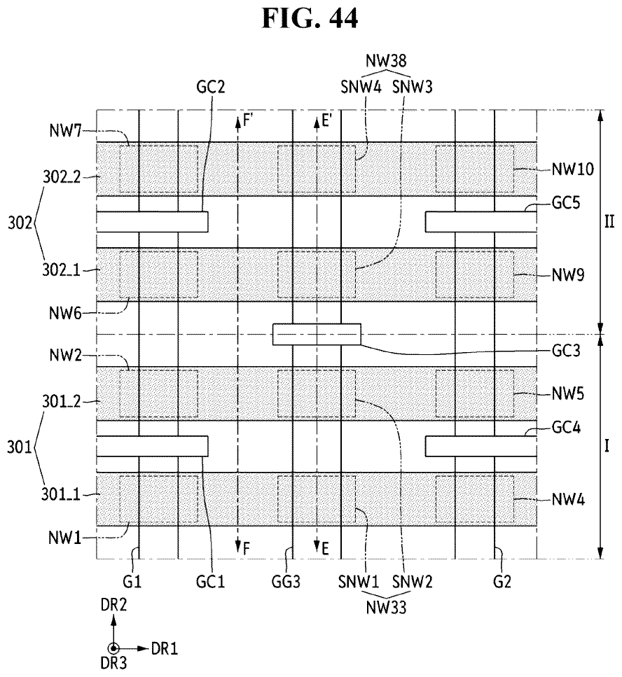

Hereinafter, the semiconductor device according to one or more example embodiments is described with reference to FIGS. 44, 45 and 46. The description focuses on the differences from the semiconductor device shown in FIGS. 1, 2, 3, 4 and 5, according to one or more example embodiments.

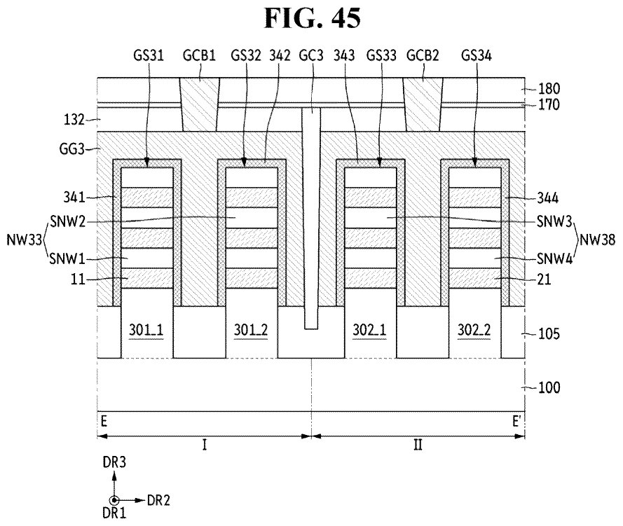

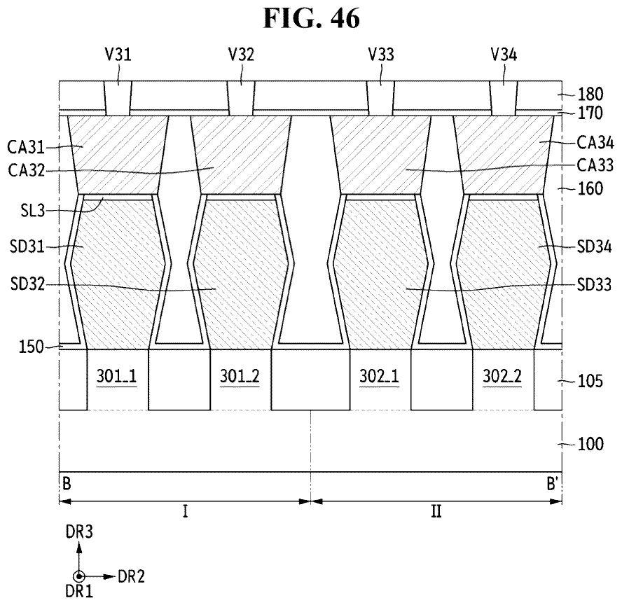

FIG. 44 is a layout diagram for explaining the semiconductor device according to one or more example embodiments. FIG. 45 is a cross-sectional view taken along the line E-E′ of FIG. 44, according to one or more example embodiments. FIG. 46 is a cross-sectional view taken along the line F-F′ of FIG. 44, according to one or more example embodiments.

Referring to FIG. 44 to FIG. 46, the semiconductor device according to one or more example embodiments may include a third plurality of nanosheets NW33 including a first and a second plurality of sub-nanosheets SNW1 and SNW2, and an eighth plurality of nanosheets NW38 including a third and a fourth plurality of sub-nanosheets SNW3 and SNW4.

For example, the first active pattern 301 may include a first portion 301_1 and a second portion 301_2, which is separated from the first portion 301_1 in the second horizontal direction DR2. The second active pattern 302 may include a first portion 302_1 and a second portion 302_2 separated from the first portion 302_1 in the second horizontal direction DR2. For example, the first ground structure GS31 may be disposed on the first portion 301_1 of the first active pattern 301. The second ground structure GS32 may be disposed on the second portion 301_2 of the first active pattern 301. The third ground structure GS33 may be disposed on the first portion 302_1 of the second active pattern 302. The fourth ground structure GS34 may be disposed on the second portion 302_2 of the second active pattern 302.

For example, the first ground structure GS31 may include the first plurality of sub-nanosheets SNW1 and the first semiconductor layer 11 positioned between the first plurality of sub-nanosheets SNW1. The second ground structure GS32 may include the second plurality of sub-nanosheets SNW2 and the first semiconductor layer 11 positioned between the second plurality of sub-nanosheets SNW2. The third ground structure GS33 may include the third plurality of sub-nanosheets SNW3 and the second semiconductor layer 21 positioned between the third plurality of sub-nanosheets SNW3. The fourth ground structure GS34 may include the fourth plurality of sub-nanosheets SNW4 and the second semiconductor layer 21 positioned between the fourth plurality of sub-nanosheets SNW4.

For example, the ground gate electrode GG3 may cover both sidewalls and the upper surface of each of the first, second, third and fourth ground structures GS31, GS32, GS33 and GS34 in the second horizontal direction DR2. For example, the first ground silicide layer 341 may be disposed between the ground gate electrode GG3 and the first ground structure GS31. The second ground silicide layer 342 may be disposed between the ground gate electrode GG3 and the second ground structure GS32. The third ground silicide layer 343 may be disposed between the ground gate electrode GG3 and the third ground structure GS33. The fourth ground silicide layer 344 may be disposed between the ground gate electrode GG3 and the fourth ground structure GS34.

For example, the first source/drain region SD31 may be disposed on the first portion 301_1 of the first active pattern 301. The second source/drain region SD32 may be disposed on the second portion 301_2 of the first active pattern 301. The third source/drain region SD33 may be disposed on the first portion 302_1 of the second active pattern 302. The fourth source/drain region SD34 may be disposed on the second portion 302_2 of the second active pattern 302. For example, the first, second, third and fourth source/drain regions SD31, SD32, SD33 and SD34 may be sequentially spaced in the second horizontal direction DR2.

For example, the first source/drain contact CA31 may be connected to the first source/drain region SD31. The second source/drain contact CA32 may be connected to the second source/drain region SD32. The third source/drain contact CA33 may be connected to the third source/drain region SD33. The fourth source/drain contact CA34 may be connected to the fourth source/drain region SD34. For example, the contact silicide layer SL3 may be disposed along the interface between the first, second, third and fourth source/drain contacts CA31 to CA34 and the first, second, third and fourth source/drain regions SD31, SD32, SD33 and SD34. For example, the first via V31 may be connected to the first source/drain contact CA31. The second via V32 may be connected to the second source/drain contact CA32. The third via V33 may be connected to the third source/drain contact CA33. The fourth via V34 may be connected to the fourth source/drain contact CA34.

While one or more example embodiments have been particularly shown and described above with reference to the accompanying drawings, it will be apparent to those skilled in the art that one or more example embodiments are not limited to these one or more example embodiments and various changes in form and details may be made therein without departing from the spirit and scope of the following claims.

What is claimed is:

1. A semiconductor device comprising:
a substrate;
an active pattern comprising a first portion and a second portion, each of the first portion and the second portion extending in a first horizontal direction on an upper surface of the substrate, and the second portion being spaced apart from the first portion in a second horizontal direction different from the first horizontal direction;
a first plurality of nanosheets stacked on the first portion of the active pattern, the first plurality of nanosheets being spaced apart from each other in a vertical direction;
a second plurality of nanosheets stacked on the second portion of the active pattern, the second plurality of nanosheets being spaced apart from each other in the vertical direction and spaced apart from the first plurality of nanosheets in the second horizontal direction;
a ground structure comprising:
a third plurality of nanosheets stacked on the first portion and the second portion of the active pattern, the third plurality of nanosheets being spaced apart from each other in the vertical direction and spaced apart from each of the first plurality of nanosheets and the second plurality of nanosheets in the first horizontal direction; and
a semiconductor layer between adjacent ones of the third plurality of nanosheets, wherein the semiconductor layer comprises silicon germanium (SiGe);
a first gate electrode extending in the second horizontal direction on each of the first portion and the second portion of the active pattern, the first gate electrode surrounding each of the first plurality of nanosheets and each of the second plurality of nanosheets;
a ground gate electrode extending in the second horizontal direction on each of the first portion and the second portion of the active pattern, the ground gate electrode being spaced apart from the first gate electrode in the first horizontal direction and covering an upper surface and sidewalls of the ground structure; and
a ground silicide layer between and in contact with the ground structure and the ground gate electrode, the ground silicide layer comprising a metal silicide.

2. The semiconductor device of claim 1, wherein a sidewall of the semiconductor layer extending in the second horizontal direction has a continuous slope profile with a sidewall of the third plurality of nanosheets extending in the second horizontal direction.

3. The semiconductor device of claim 1, further comprising:
a field insulating layer surrounding a sidewall of the active pattern on the upper surface of the substrate, and in contact with a bottom surface of the ground gate electrode.

4. The semiconductor device of claim 1, wherein each of the third plurality of nanosheets and the semiconductor layer comprises doped impurities.

5. The semiconductor device of claim 1, wherein the upper surface of the ground structure is coplanar with an upper surface of an uppermost nanosheet of the first plurality of nanosheets.

6. The semiconductor device of claim 1, further comprising:
a gate cut between the first portion of the active pattern and the second portion of the active pattern,
wherein the gate cut separates the first gate electrode and extends in the second horizontal direction.

7. The semiconductor device of claim 1, further comprising:
a fourth plurality of nanosheets stacked on the first portion of the active pattern, the fourth plurality of nanosheets being spaced apart from each other in the vertical direction and spaced apart from the third plurality of nanosheets in the first horizontal direction;
a fifth plurality of nanosheets stacked on the second portion of the active pattern, the fifth plurality of nanosheets being spaced apart from each other in the vertical direction, spaced apart from the third plurality of nanosheets in the first horizontal direction, and spaced apart from the fourth plurality of nanosheets in the second horizontal direction; and
a second gate electrode extending in the second horizontal direction on each of the first portion and the second portion of the active pattern, the second gate electrode being spaced apart from the ground gate electrode in the first horizontal direction and surrounding each of the fourth plurality of nanosheets and the fifth plurality of nanosheets.

8. The semiconductor device of claim 1, further comprising:
a gate spacer on an upper surface of an uppermost nanosheet of the third plurality of nanosheets and in contact with both sidewalls of the ground gate electrode in the first horizontal direction.

9. The semiconductor device of claim 8, wherein sidewalls of the ground silicide layer, which are spaced apart in the first horizontal direction, are in contact with the gate spacer.

10. The semiconductor device of claim 1, wherein the active pattern further comprises a third portion connecting the first portion of the active pattern and the second portion of the active pattern,
wherein the third portion of the active pattern overlaps the ground gate electrode in the vertical direction, and
wherein the third portion of the active pattern does not overlap the first gate electrode in the vertical direction.

11. The semiconductor device of claim 10, wherein the third plurality of nanosheets overlaps each of the first portion, the second portion and the third portion of the active pattern in the vertical direction, and
wherein a width of the third plurality of nanosheets in the second horizontal direction is greater than a width of the first plurality of nanosheets in the second horizontal direction.

12. The semiconductor device of claim 1, further comprising:
a first capping pattern extending in the second horizontal direction on an upper surface of the first gate electrode; and
a second capping pattern extending in the second horizontal direction on an upper surface of the ground gate electrode,
wherein an upper surface of the first capping pattern and an upper surface of the second capping pattern are coplanar.

13. A semiconductor device comprising:
a substrate comprising a P-channel Metal-Oxide-Semiconductor (PMOS) region and an N-channel Metal-Oxide-Semiconductor (NMOS) region;
a first active pattern extending in a first horizontal direction on an upper surface of the substrate in the PMOS region;
a second active pattern extending in the first horizontal direction on the upper surface of the substrate in the NMOS region, the second active pattern being spaced apart from the first active pattern in a second horizontal direction different from the first horizontal direction;
a field insulating layer on the upper surface of the substrate and surrounding sidewalls the first active pattern and sidewalls of the second active pattern;
a first plurality of nanosheets stacked on the first active pattern and spaced apart from each other in a vertical direction;
a first ground structure comprising:
a second plurality of nanosheets stacked on the first active pattern, the second plurality of nanosheets being spaced apart from each other in the vertical direction and spaced apart from the first plurality of nanosheets in the first horizontal direction; and
a first semiconductor layer between adjacent ones of the second plurality of nanosheets, the first semiconductor layer comprising silicon germanium (SiGe);
a third plurality of nanosheets stacked on the second active pattern, the third plurality of nanosheets being spaced apart from each other in the vertical direction and spaced apart from the first plurality of nanosheets in the second horizontal direction;
a second ground structure comprising:
a fourth plurality of nanosheets stacked on the second active pattern, the fourth plurality of nanosheets being spaced apart from each other in the vertical direction and spaced apart from the third plurality of nanosheets in the first horizontal direction; and
a second semiconductor layer between adjacent ones of the fourth plurality of nanosheets, the second semiconductor layer being spaced apart from the first ground structure in the second horizontal direction, the second semiconductor layer comprising silicon germanium (SiGe);
a gate electrode extending in the second horizontal direction on each of the first active pattern and the second active pattern and surrounding each of the first plurality of nanosheets and the third plurality of nanosheets; and
a ground gate electrode extending in the second horizontal direction on each of the first active pattern and the second active pattern, the ground gate electrode being spaced apart from the gate electrode in the first horizontal direction, the ground gate electrode covering an upper surface and sidewalls of the first ground structure and upper surface and sidewalls of the second ground structure, the ground gate electrode being in contact with an upper surface of the field insulating layer.

14. The semiconductor device of claim 13, wherein each of the second plurality of nanosheets and the first semiconductor layer comprises a doped n-type impurity, and
wherein each of the fourth plurality of nanosheets and the second semiconductor layer comprises a doped p-type impurity.

15. The semiconductor device of claim 13, further comprising:
a first ground silicide layer between the first ground structure and the ground gate electrode, the first ground silicide layer being in contact with each of the first ground structure and the ground gate electrode, the first ground silicide layer comprising a metal silicide; and
a second ground silicide layer between the second ground structure and the ground gate electrode, the second ground silicide layer being in contact with each of the second ground structure and the ground gate electrode, the second ground silicide layer comprising a metal silicide.

16. The semiconductor device of claim 13, wherein the first active pattern comprises:
a first portion extending in the first horizontal direction;
a second portion extending in the first horizontal direction, the second portion being spaced apart from the first portion in the second horizontal direction; and
a third portion connecting the first portion and the second portion,
wherein the third portion of the first active pattern overlaps the ground gate electrode in the vertical direction, and
wherein the third portion of the first active pattern does not overlap the gate electrode in the vertical direction.

17. The semiconductor device of claim 16, further comprising:
a gate cut between the first portion of the first active pattern and the second portion of the first active pattern, the gate cut being spaced apart from the third portion of the first active pattern in the first horizontal direction and separating the gate electrode in the second horizontal direction.

18. The semiconductor device of claim 13, wherein a width of the second plurality of nanosheets in the second horizontal direction is greater than a width of the first plurality of nanosheets in the second horizontal direction, and
wherein a width of the fourth plurality of nanosheets in the second horizontal direction is greater than a width of the third plurality of nanosheets in the second horizontal direction.

19. The semiconductor device of claim 13, wherein an upper surface of the ground gate electrode is higher than an upper surface of the gate electrode in the vertical direction.

20. A semiconductor device comprising:
a substrate comprising a P-channel Metal-Oxide-Semiconductor (PMOS) region and an N-channel Metal-Oxide-Semiconductor (NMOS) region;
a first active pattern extending in a first horizontal direction on an upper surface of the substrate in the PMOS region, the first active pattern comprising:
a first portion;
a second portion spaced apart from the first portion in a second horizontal direction different from the first horizontal direction; and
a third portion connecting the first portion and the second portion;
a second active pattern extending in the first horizontal direction on the upper surface of the substrate in the NMOS region, the second active pattern being spaced apart from the first active pattern in the second horizontal direction;
a first ground structure comprising:
a first plurality of nanosheets stacked on each of the first portion, the second portion and the third portion of the first active pattern, the first plurality of nanosheets being spaced apart from each other in a vertical direction; and
a first semiconductor layer between adjacent ones of the first plurality of nanosheets, wherein the first semiconductor layer comprising silicon germanium (SiGe);
a second ground structure spaced apart from the first ground structure in the second horizontal direction, the second ground structure comprising:
a second plurality of nanosheets stacked on the second active pattern, the second plurality of nanosheets being spaced apart from each other in the vertical direction; and
a second semiconductor layer between adjacent ones of the second plurality of nanosheets, the second semiconductor layer comprising silicon germanium (SiGe);
a first gate electrode extending in the second horizontal direction on each of the first portion and the second portion of the first active pattern and on the second active pattern;
a ground gate electrode extending in the second horizontal direction on each of the first portion, the second portion and the third portion of the first active pattern and on the second active pattern, the ground gate electrode being spaced apart from the first gate electrode in the first horizontal direction, the ground gate electrode covering an upper surface and sidewalls of the first ground structure and an upper surface and sidewalls of the second ground structure;
a second gate electrode extending in the second horizontal direction on each of the first portion and the second portion of the first active pattern and on the second active pattern, the second gate electrode being spaced apart from the ground gate electrode in the first horizontal direction;
a first gate cut between the first portion of the first active pattern and the second portion of the first active pattern, the first gate cut separating the first gate electrode in the second horizontal direction;
a second gate cut between the first ground structure and the second ground structure, the second gate cut separating the ground gate electrode in the second horizontal direction; and
a third gate cut between the first portion of the first active pattern and the second portion of the first active pattern, the third gate cut separating the second gate electrode in the second horizontal direction,
wherein the third portion of the first active pattern is between the first gate cut and the third gate cut.
